(19) United States
(12) Patent Application Publication
(10) Pub. No.: US 2026/0214900 A1
(43) Pub. Date: Jul. 23, 2026

(54) SEMICONDUCTOR MEMORY DEVICE

(71) Applicant: SK hynix Inc., Icheon-si Gyeonggi-do (KR)

(72) Inventors: Won Geun CHOI, Icheon-si Gyeonggi-do (KR); Mi Seong PARK, Icheon-si Gyeonggi-do (KR); Jung Shik JANG, Icheon-si Gyeonggi-do (KR)

(73) Assignee: SK hynix Inc., Icheon-si Gyeonggi-do (KR)

(21) Appl. No.: 19/569,896

(22) Filed: Mar. 17, 2026

Related U.S. Application Data
(63) Continuation-in-part of application No. 18/098,552, filed on Jan. 18, 2023, now Pat. No. 12,588,203.

(30) Foreign Application Priority Data
Jul. 15, 2022 (KR) 10-2022-0087674

(51) Int. Cl. H10B 43/27; G11C 5/06; G11C 16/04; H10B 43/10; H10B 43/35

(52) U.S. Cl. CPC H10B 43/27; G11C 5/063; G11C 16/0483; H10B 43/10; H10B 43/35

(57) ABSTRACT

A semiconductor memory device is provided. The semiconductor memory device includes a gate stacked structure including conductive layers, each of the conductive layers extending in a first direction and a second direction, wherein the conductive layers are stacked to be spaced apart from each other in a third direction. Also, the semiconductor memory device includes a first insulating layer and an intermediate insulating layer, which are stacked in the third direction over the gate stacked structure, a first channel structure and a second channel structure extending through the gate stacked structure and spaced apart from each other in the second direction, an insulating material extending through the intermediate insulating layer, and a bit line contact extending through the first insulating layer.

### CROSS-REFERENCE TO RELATED APPLICATION

The present application is a continuation-in-part of U.S. patent application Ser. No. 18/098,552, filed on Jan. 18, 2023, which claims priority under 35 U.S.C. § 119(a) to Korean patent application number 10-2022-0087674, filed on Jul. 15, 2022, in the Korean Intellectual Property Office, the entire contents of which applications are incorporated herein by reference.

### BACKGROUND

### 1. Technical Field

Various embodiments of the present disclosure generally relate to a semiconductor memory device, and more particularly, to a three-dimensional semiconductor memory device.

### 2. Related Art

A semiconductor memory device may include a plurality of memory cells capable of storing data. A plurality of memory cells of a three-dimensional semiconductor memory device may be arranged in three dimensions. In the three-dimensional semiconductor memory device, the plurality of memory cells may be coupled in series by a channel structure that passes through a gate stacked structure.

### SUMMARY

According to an embodiment of the present disclosure, a semiconductor memory device may include a gate stacked structure including conductive layers, each of the conductive layers extending in a first direction and a second direction, wherein the conductive layers are stacked to be spaced apart from each other in a third direction, a first insulating layer, an intermediate insulating layer, and a second insulating layer, which are stacked in the third direction over the gate stacked structure, a first channel structure and a second channel structure extending through the gate stacked structure and spaced apart from each other in the second direction, a first bit line disposed in the second insulating layer and extending in the second direction, and a first bit line contact extending through the first insulating layer to be positioned between the first bit line and the first channel structure. The intermediated insulating layer may include a trench extending in a diagonal direction between the first and second directions, and the second insulating layer may include a horizontal portion disposed over the intermediate insulating layer, and a protrusion extending from the horizontal portion to fill the trench.

According to an embodiment of the present disclosure, a semiconductor memory device may include a gate stacked structure including conductive layers, each of the conductive layers extending in a first direction and a second direction, wherein the conductive layers are stacked to be spaced apart from each other in a third direction, a first channel structure and a second channel structure extending through the gate stacked structure and spaced apart from each other in the second direction, a first insulating layer, an intermediate insulating layer, and a second insulating layer, which are stacked in the third direction over the gate stacked structure, a first insulating line and a second insulating line extending through the intermediate insulating layer and the first insulating layer, extending in the second direction, and spaced apart from each other in the first direction, a first bit line contact extending through the first insulating line and the first insulating layer to overlap the first channel structure in the third direction, and a second bit line contact extending through the second insulating line and the first insulating layer to overlap the second channel structure in the third direction.

### BRIEF DESCRIPTION OF THE DRAWINGS

FIG. 1 is a block diagram illustrating a semiconductor memory device according to an embodiment;

FIG. 2 is a circuit diagram illustrating a memory cell array according to an embodiment;

FIGS. 3A and 3B are diagrams illustrating components of a semiconductor memory device that are vertically arranged according to embodiments;

FIG. 4 is a perspective view illustrating a semiconductor memory device according to an embodiment;

FIG. 5 is a plan view illustrating an arrangement of a plurality of channel structures, a plurality of channel contacts, a plurality of bit line contacts, and a plurality of bit lines of a semiconductor memory device shown in FIG. 4;

FIGS. 6A, 6B, and 6C are cross-sectional diagrams of a semiconductor memory device which are taken along lines A1-A1′, B1-B1′, and C1-C1′ of FIG. 5, respectively;

FIGS. 7A, 7B, and 7C are plan views illustrating layouts of a semiconductor memory device shown in FIG. 4 at different depths;

FIG. 8 is a plan view illustrating an arrangement of an etch stop layer and a plurality of bit line contacts of a semiconductor memory device according to an embodiment;

FIGS. 9A, 9B, and 9C are cross-sectional diagrams of a semiconductor memory device which are taken along lines A2-A2′, B2-B2′, and C2-C2′ of FIG. 8, respectively;

FIGS. 10A and 10B are cross-sectional diagrams illustrating a structure in which a doped semiconductor structure and a channel structure are coupled according to embodiments;

FIGS. 11A, 11B, 12A, 12B, 13A, 13B, 14A, 14B, 15A, 15B, and 15C are diagrams illustrating a method of manufacturing a semiconductor memory device according to an embodiment;

FIGS. 16A, 16B, 17A, 17B, 18A, 18B, 19A, and 19B are diagrams illustrating a method of manufacturing a semiconductor memory device according to an embodiment;

FIG. 20 is a block diagram illustrating a configuration of a memory system according to an embodiment;

FIG. 21 is a block diagram illustrating a configuration of a computing system according to an embodiment;

FIG. 22 is a diagram illustrating the structure of a semiconductor memory device according to an embodiment;

FIG. 23 is a diagram illustrating the structure of a semiconductor memory device according to an embodiment;

FIG. 24 is a diagram illustrating the structure of a semiconductor memory device according to an embodiment;

FIG. 25A is a diagram illustrating the structure of a semiconductor memory device according to an embodiment;

FIG. 25B is a diagram illustrating the structure of a semiconductor memory device according to an embodiment;

FIG. 25C is a diagram illustrating the structure of a semiconductor memory device according to an embodiment;

FIG. 26A is a diagram illustrating the structure of a semiconductor memory device according to an embodiment;

FIG. 26B is a diagram illustrating the structure of a semiconductor memory device according to an embodiment;

FIG. 26C is a diagram illustrating the structure of a semiconductor memory device according to an embodiment;

FIG. 26D is a diagram illustrating the structure of a semiconductor memory device according to an embodiment;

FIGS. 27A to 27D are a diagram illustrating the structure of a semiconductor memory device according to an embodiment; and

FIGS. 28A and 28B are diagrams illustrating the structure of a semiconductor memory device according to an embodiment.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first,” “second,” etc. may be used herein to describe various elements, these elements should not be limited by these terms. These terms are used for distinguishing one element from another element and not to suggest a number or order of elements.

Various embodiments are directed to a semiconductor memory device capable of securing process margins and improving operational reliability thereof.

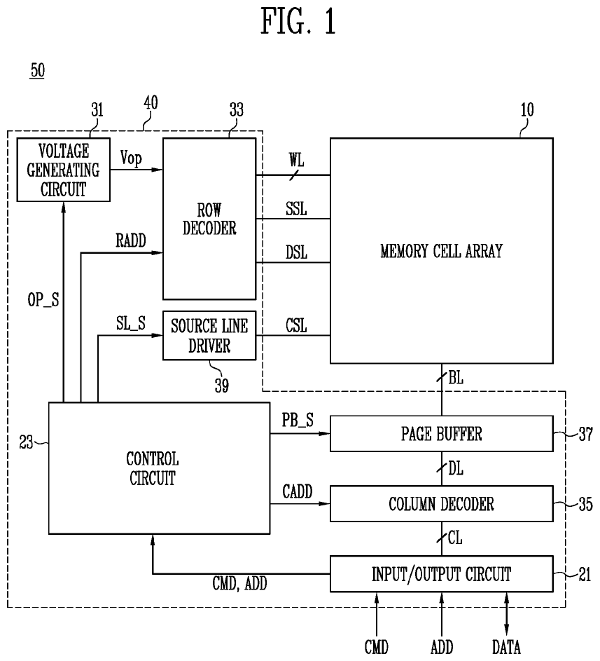

FIG. 1 is a block diagram illustrating a semiconductor memory device 50 according to an embodiment.

Referring to FIG. 1, the semiconductor memory device 50 may include a peripheral circuit structure 40 and a memory cell array 10.

The peripheral circuit structure 40 may be configured to perform a program operation to store data in the memory cell array 10, a read operation to output the data stored in the memory cell array 10, and an erase operation to erase the data stored in the memory cell array 10. According to an embodiment, the peripheral circuit structure 40 may include an input/output circuit 21, a control circuit 23, a voltage generating circuit 31, a row decoder 33, a column decoder 35, a page buffer 37, and a source line driver 39.

The memory cell array 10 may be connected to the peripheral circuit structure 40 through a common source line CSL, a bit line BL, a drain select line DSL, a word line WL, and a source select line SSL.

The input/output circuit 21 may transfer a command CMD and an address ADD received from an external device (for example, a memory controller) of the semiconductor memory device 50 to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operating voltages Vop used for performing the program operation, the read operation, and the erase operation in response to the operation signal OP_S.

The row decoder 33 may transfer the operating voltages Vop to the drain select line DSL, the word line WL, and the source select line SSL in response to the row address RADD.

The column decoder 35 may transmit the data DATA input from the input/output circuit 21 to the page buffer 37 or transmit the data DATA stored in the page buffer 37 to the input/output circuit 21 in response to the column address CADD. The column decoder 35 may exchange the data DATA with the input/output circuit 21 through a column line CL. The column decoder 35 may exchange the data DATA with the page buffer 37 through a data line DL.

The page buffer 37 may store read data received through the bit line BL in response to the page buffer control signal PB_S. The page buffer 37 may sense a voltage or a current of the bit line BL during the read operation.

The source line driver 39 may control a voltage applied to the common source line CSL in response to the source line control signal SL_S.

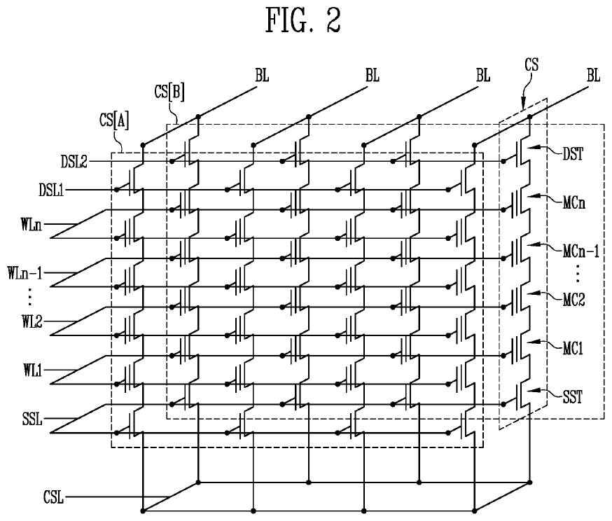

FIG. 2 is a circuit diagram illustrating a memory cell array according to an embodiment.

Referring to FIG. 2, the memory cell array may include a plurality of memory cell strings CS.

Each of the memory cell strings CS may include at least one source select transistor SST, a plurality of memory cells MC1 to MCn and at least one drain select transistor DST. The plurality of memory cells MC1 to MCn may be coupled in series between the source select transistor SST and the drain select transistor DST. The source select transistor SST, the plurality of memory cells MC1 to MCn, and the drain select transistor DST may be coupled in series by a channel structure.

The plurality of memory cell strings CS may be connected in parallel to the common source line CSL. Each of the memory cell strings CS may be connected to a corresponding one bit line of the plurality of bit lines BL. The common source line CSL and the plurality of bit lines BL may be connected to channel structures of the plurality of memory cell strings CS.

The plurality of memory cells MC1 to MCn of each of the memory cell strings CS may be connected to the common source line CSL via the source select transistor SST. The plurality of memory cells MC1 to MCn of each of the memory cell strings CS may be connected to a corresponding bit line BL via the drain select transistor DST.

Each of the memory cell strings CS may be connected to the source select line SSL, a plurality of word lines WL1 to WLn, and a drain select line DSL1 or DSL2. The source select line SSL may serve as a gate electrode of the source select transistor SST. The plurality of word lines WL1 to WLn may serve as gate electrodes of the plurality of memory cells MC1 to MCn. The drain select line DSL1 or DSL2 may serve as a gate electrode of the drain select transistor DST.

Each of the plurality of word lines WL1 to WLn may be configured to control the plurality of memory cell strings CS. The plurality of memory cell strings CS may be divided into two or more memory cell string groups. Each of the bit lines BL may be connected to the memory cell strings CS included in different memory cell string groups. According to an embodiment, one memory cell string of a first memory cell string group CS[A] and one memory cell string of a second memory cell string group CS[B] may be connected to each of the bit lines BL. The first memory cell string group CS[A] and the second memory cell string group CS[B] may be controlled independently of each other by separate drain select lines or separate source select lines. According to an embodiment, the first memory cell string group CS[A] may be connected to a first drain select line DSL1 and the second memory cell string group CS[B] may be connected to a second drain select line DSL2. The first memory cell string group CS[A] and the second memory cell string group CS[B] may be connected to the same source select line SSL. However, embodiments of the present disclosure are not limited thereto. According to another embodiment, two or more memory cell strings connected to the same bit line BL may be connected to the same drain select line and may be connected to two or more separate source select lines in a one-to-one manner. According to another embodiment, two or more memory cell strings connected to the same bit line BL may be connected to two or more separate drain select lines in a one-to-one manner and may be connected to two or more separate source select lines in a one-to-one manner.

An operating voltage for precharging a channel structure of a memory cell string CS corresponding to each of the bit lines BL may be applied to each of the bit lines BL. The bit line BL may be connected to the channel structure of the memory cell string CS through a bit line contact.

An operating voltage for discharging a potential of the channel structure of the memory cell string CS may be applied to the common source line CSL. The common source line CSL may be connected to the memory cell string CS through a doped semiconductor structure.

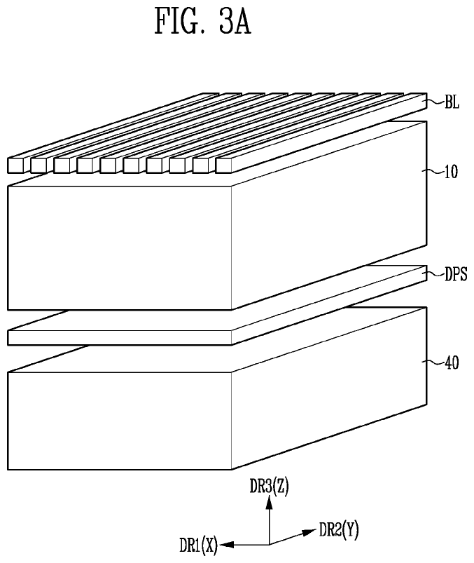

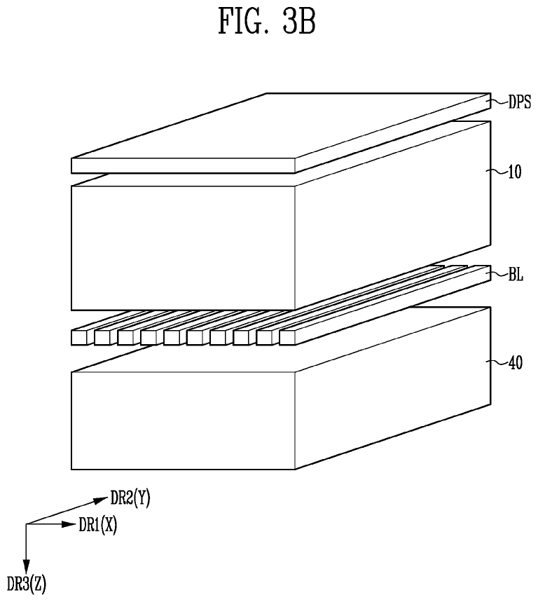

FIGS. 3A and 3B are diagrams illustrating components of a semiconductor memory device that are vertically arranged according to embodiments.

Referring to FIGS. 3A and 3B, the semiconductor memory device may include a doped semiconductor structure DPS, the memory cell array 10, the peripheral circuit structure 40, and the plurality of bit lines BL. The doped semiconductor structure DPS may have a plate shape that extends in a first direction DR1 and a second direction DR2 and may face the plurality of bit lines BL in a third direction DR3. According to an embodiment, the first direction DR1, the second direction DR2, and the third direction DR3 may correspond to an X axis, a Y axis, and a Z axis, respectively. The doped semiconductor structure DPS may be connected to the common source line CSL shown in FIG. 2. The memory cell array 10 may be disposed between the plurality of bit lines BL and the doped semiconductor structure DPS. In an embodiment, the doped semiconductor structure DPS may be disposed between the memory cell array 10 and the peripheral circuit structure 40 as shown in, for example, FIG. 3A.

Referring to FIG. 3A, the peripheral circuit structure 40 of the semiconductor memory device may be adjacent to the doped semiconductor structure DPS. Although not illustrated in FIG. 3A, a plurality of interconnections, or a plurality of interconnections and a plurality of conductive bonding pads may be disposed between the peripheral circuit structure 40 and the doped semiconductor structure DPS.

Referring to FIG. 3B, the peripheral circuit structure 40 of the semiconductor memory device may be adjacent to the plurality of bit lines BL. Although not illustrated in FIG. 3B, a plurality of interconnections, or a plurality of interconnections and a plurality of conductive bonding pads may be disposed between the peripheral circuit structure 40 and the plurality of bit lines BL.

Referring to FIGS. 3A and 3B, the doped semiconductor structure DPS, the memory cell array 10, and the plurality of bit lines BL may overlap with the peripheral circuit structure 40.

According to an embodiment, a process for forming the memory cell array 10 may be performed on the peripheral circuit structure 40. According to another embodiment, a first structure including the memory cell array 10 may be formed separately from a second structure including the peripheral circuit structure 40. When the first structure and the second structure are formed separately from each other, the first structure and the second structure may be bonded together by a plurality of conductive bonding pads.

Hereinafter, embodiments of the memory cell array 10 shown in FIGS. 3A and 3B are described in more detail.

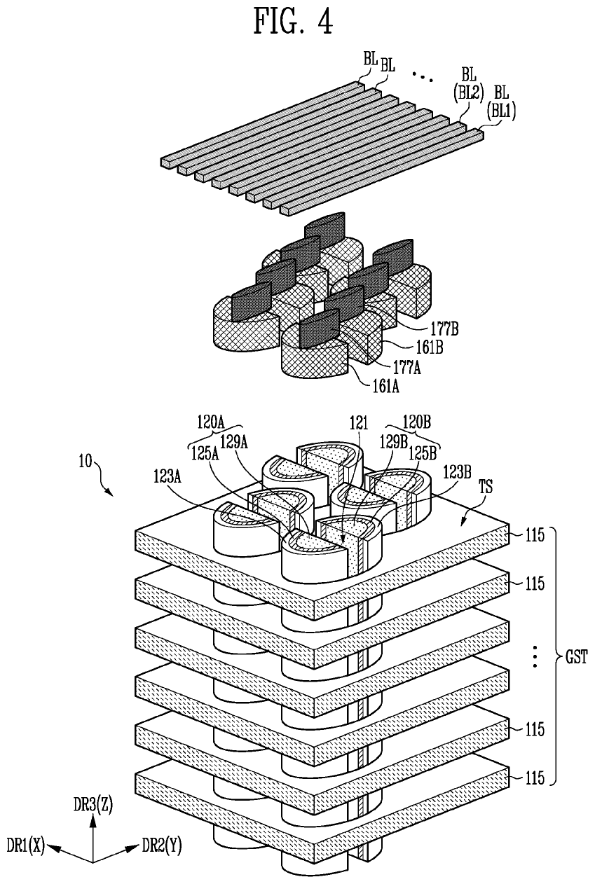

FIG. 4 is a perspective view illustrating a semiconductor memory device according to an embodiment. For convenience of recognition, illustration of some components is omitted.

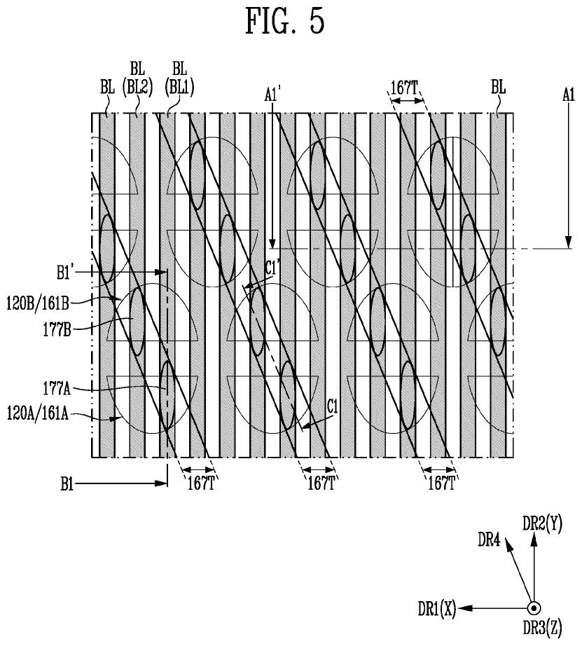

FIG. 5 is a plan view illustrating an arrangement of a plurality of channel structures, a plurality of channel contacts, a plurality of bit line contacts, and a plurality of bit lines of the semiconductor memory device shown in FIG. 4.

Referring to FIGS. 4 and 5, the semiconductor memory device may include the memory cell array 10 connected to the plurality of bit lines BL. The memory cell array 10 may be provided as a three-dimensional memory cell array. To provide the three-dimensional memory cell array, the memory cell array 10 may include a gate stacked structure GST including a plurality of conductive layers 115, a plurality of channel structures 120A and 120B that pass through the gate stacked structure GST, and a plurality of memory layers 123A and 123B between the plurality of channel structures 120A and 120B and the gate stacked structure GST.

Each of the conductive layers 115 may have a plate shape that extends in the first direction DR1 and the second direction DR2 that are defined with reference to FIGS. 3A and 3B. A top surface TS of each of the conductive layers 115 may extend in the first direction DR1 and the second direction DR2 and face the third direction DR3 that is defined with reference to FIGS. 3A and 3B.

The plurality of conductive layers 115 may be stacked to be spaced apart from each other in the third direction DR3. The plurality of conductive layers 115 may be provided as at least one layer of the source select line SSL, the plurality of word lines WL1 to WLn, and at least one layer of the drain select line DSL1 or DSL2 shown in FIG. 2. Each of the conductive layers 115 may include at least one of a doped semiconductor layer, a metal layer, and a conductive metal nitride layer. The doped semiconductor layer may include a doped silicon layer. The metal layer may include tungsten, copper, molybdenum, or the like. The conductive metal nitride layer may include a titanium nitride, a tantalum nitride, or the like.

The gate stacked structure GST may include a plurality of channel holes 121. The plurality of channel holes 121 may extend in the third direction DR3 to pass through the plurality of conductive layers 115. In an embodiment, to increase arrangement density of the plurality of channel holes 121 in the gate stacked structure GST, the plurality of channel holes 121 may be arranged in a zigzag pattern.

The plurality of channel structures 120A and 120B may include a plurality of first channel structures 120A and a plurality of second channel structures 120B that form a plurality of pairs. The plurality of pairs of the first channel structure 120A and the second channel structure 120B may correspond to the plurality of channel holes 121 in a one-to-one manner. The first channel structure 120A and the second channel structure 120B of each of the plurality of pairs may be arranged to be spaced apart from each other in the second direction DR2 in the corresponding channel hole 121.

The plurality of memory layers 123A and 123B may include a plurality of first memory layers 123A and a plurality of second memory layers 123B that form a plurality of pairs. The plurality of pairs of the first memory layer 123A and the second memory layer 123B may correspond to the plurality of channel holes 121 in a one-to-one manner. The first memory layer 123A and the second memory layer 123B of each of the plurality of pairs may be arranged to be spaced apart from each other in the second direction DR2 in the corresponding channel hole 121.

The plurality of pairs of the first memory layer 123A and the second memory layer 123B may correspond to the plurality of pairs of the first channel structure 120A and the second channel structure 120B in a one-to-one manner. The first memory layer 123A may be disposed between the corresponding first channel structure 120A and the gate stacked structure GST and the second memory layer 123B may be disposed between the corresponding second channel structure 120B and the gate stacked structure GST.

A plurality of memory cells of the memory cell array 10 may be provided at intersections of conductive layers, which are provided as word lines among the plurality of conductive layers 115, and the first channel structure 120A and intersections of the conductive layers, which are provided as the word lines among the plurality of conductive layers 115, and the second channel structure 120B. Because the first channel structure 120A and the second channel structure 120B of each of the plurality of pairs are spaced apart from each other in the same channel hole 121, a memory cell string that is defined along the first channel structure 120A and a memory cell string that is defined along the second channel structure 120B may be controlled independently of each other. The first channel structure 120A and the second channel structure 120B of each of the plurality of pairs may be surrounded by each of the conductive layers 115. In other words, each of the conductive layers 115 may continuously extend to surround the first channel structure 120A and the second channel structure 120B of each of the plurality of pairs in a plane in which each of the conductive layers 115 is disposed. According to an embodiment, each of the conductive layers 115 may extend along an XY plane to surround the first channel structure 120A and the second channel structure 120B of each of the plurality of pairs. Accordingly, the first channel structure 120A and the second channel structure 120B of each of the plurality of pairs may be controlled by the same conductive layer.

The memory cell array 10 may be connected to the plurality of bit lines BL through a plurality of bit line contacts 177A and 177B. The plurality of bit line contacts 177A and 177B may include a conductive material and may include a plurality of first bit line contacts 177A and a plurality of second bit line contacts 177B that form a plurality of pairs. The plurality of pairs of the first bit line contact 177A and the second bit line contact 177B may correspond to the plurality of pairs of the first channel structure 120A and the second channel structure 120B in a one-to-one manner. The first bit line contact 177A may be connected to the corresponding first channel structure 120A and the second bit line contact 177B may be connected to the corresponding second channel structure 120B.

The semiconductor memory device may further include a plurality of channel contacts 161A and 161B between the plurality of bit line contacts 177A and 177B and the memory cell array 10. More specifically, the plurality of channel contacts 161A may be disposed between the plurality of bit line contacts 177A and the memory cell array 10, and the plurality of channel contacts 161B may be disposed between the plurality of bit line contacts 177B and the memory cell array 10. The plurality of channel contacts 161A and 161B may include a conductive material and may have similar cross-sectional structures to the plurality of channel structures 120A and 120B. The cross-sectional structures of the plurality of channel structures 120A and 120B may be associated with cross-sectional structures of the plurality of channel holes 121. Each of the plurality of channel holes 121 may have a width in the second direction DR2 which is greater than a width in the first direction DR1. Due to the widths that are different according to the directions, each of the channel holes 121 may be formed to have a cross-sectional structure that has a shape including, but not limited to, a circle, an ellipse, a square, or a polygon. The first channel structure 120A and the second channel structure 120B of each of the plurality of pairs may be disposed at opposite ends of the corresponding channel hole 121 and may have shapes corresponding to cross-sectional structures of the opposite ends of the channel hole 121. According to an embodiment, a shape of the cross-sectional structure of the channel hole 121 may be an ellipse which has the minor axis extending in the first direction DR1 and the major axis extending in the second direction DR2, and the first channel structure 120A and the second channel structure 120B of each of the plurality of pairs may have semi-ellipse shapes that are symmetrical to each other to correspond to the above-described shape of the cross-sectional structure of the channel hole 121. Each of the plurality of channel contacts 161A and 161B may have a semi-ellipse shape similar to the shape of the cross-sectional structure of the corresponding channel structure.

The plurality of channel contacts 161A and 161B may include a plurality of first channel contacts 161A and a plurality of second channel contacts 161B that form a plurality of pairs. The plurality of pairs of the first channel contact 161A and the second channel contact 161B may correspond to the plurality of pairs of the first channel structure 120A and the second channel structure 120B in a one-to-one manner. The first channel contact 161A may contact the corresponding first channel structure 120A and the second channel contact 161B may contact the corresponding second channel structure 120B. The first channel contact 161A and the second channel contact 161B that form each of the plurality of pairs may be arranged in a diagonal direction DR4 between the first direction DR1 and the second direction DR2.

Hereinafter, an embodiment in which the plurality of channel structures 120A and 120B are connected to the plurality of bit lines BL via the plurality of channel contacts 161A and 161B and the plurality of bit line contacts 177A and 177B will be described. However, embodiments of the present disclosure are not limited thereto. For example, the plurality of channel contacts 161A and 161B may be omitted in some embodiments. According to an embodiment in which the plurality of channel contacts 161A and 161B are omitted, the first bit line contact 177A may contact the corresponding first channel structure 120A and the second bit line contact 177B may contact the corresponding second channel structure 120B.

The plurality of bit lines BL may extend in parallel to each other and include a conductive material. The plurality of bit lines BL may be spaced apart from each other in the first direction DR1 and may extend in the second direction DR2. Two or more bit lines BL may overlap with the first channel structure 120A and the second channel structure 120B of each of the plurality of pairs and different bit lines may be connected to the first channel structure 120A and the second channel structure 120B of each of the plurality of pairs. According to an embodiment, the plurality of bit lines BL may include a first bit line BL1 that is connected to the first channel structure 120A and a second bit line BL2 that is connected to the second channel structure 120B of the first channel structure 120A and the second channel structure 120B of each of the plurality of pairs. The first bit line contact 177A and the second bit line contact 177B of each of the plurality of pairs may be connected to the corresponding first bit line BL1 and the corresponding second bit line BL2, respectively.

According to the above-described structure, one of the first channel structure 120A and the second channel structure 120B that form a pair may be selected by selecting one of the plurality of conductive layers 115 and one of the first bit line BL1 and the second bit line BL2.

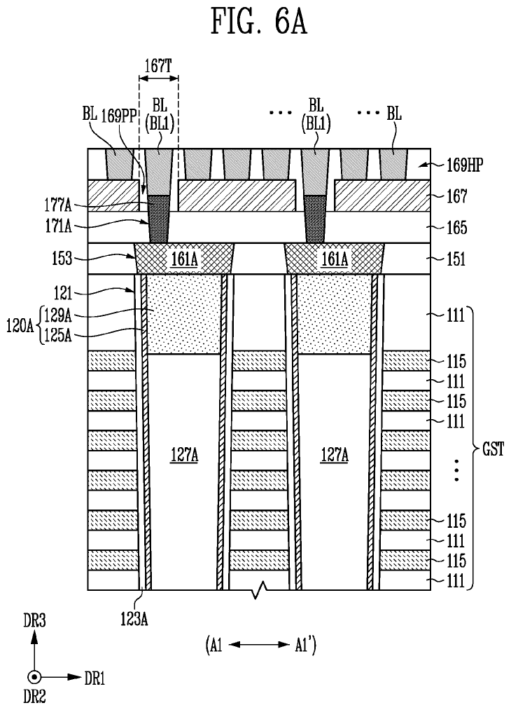

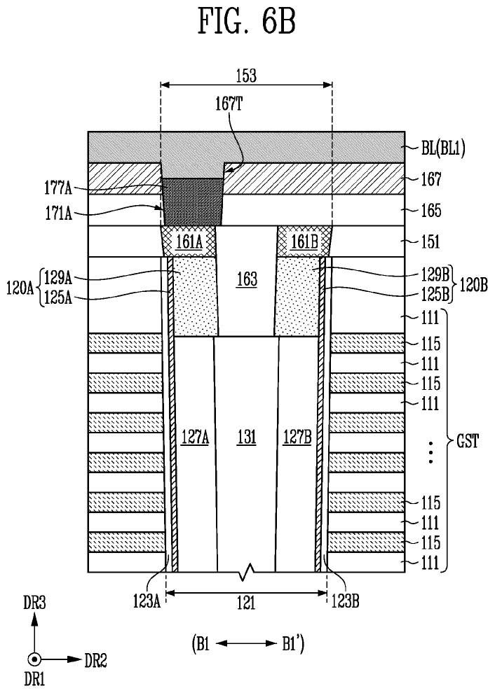

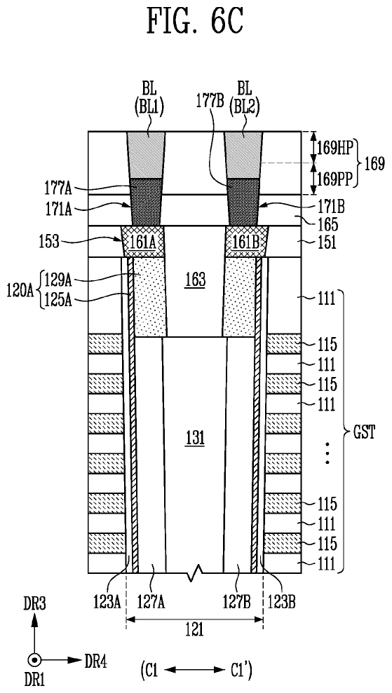

FIGS. 6A, 6B, and 6C are cross-sectional diagrams of a semiconductor memory device which are taken along lines A1-A1′, B1-B1′, and C1-C1′ of FIG. 5, respectively.

Referring to FIGS. 4, 5, 6A, 6B, and 6C, the gate stacked structure GST may include a plurality of interlayer insulating layers 111 that are stacked alternately with the plurality of conductive layers 115 in the third direction DR3. The plurality of interlayer insulating layers 111 may include an insulating material such as a silicon oxide.

The channel hole 121 may extend in the third direction DR3 to pass through the plurality of interlayer insulating layers 111 and the plurality of conductive layers 115. The channel hole 121 may be divided into a first region and a second region with a vertical insulating structure interposed therebetween. According to an embodiment, a first vertical insulating structure 131 and a second vertical insulating structure 163 may be disposed in a central region of the channel hole 121. The second vertical insulating structure 163 may be disposed over the first vertical insulating structure 131.

The first channel structure 120A and the second channel structure 120B of each of the plurality of pairs may be disposed in the first region and the second region of the channel hole 121, respectively, with the first and second vertical insulating structures 131 and 163 interposed therebetween. Each of the first channel structure 120A and the second channel structure 120B may include a channel layer 125A or 125B and a capping doped semiconductor layer 129A or 129B.

A first channel layer 125A of the first channel structure 120A may extend in the third direction DR3 along an inner wall of the first memory layer 123A and a second channel layer 125B of the second channel structure 120B may extend in the third direction DR3 along an inner wall of the second memory layer 123B. The first channel layer 125A and the second channel layer 125B may include a semiconductor material such as silicon or germanium. The first channel layer 125A and the second channel layer 125B may be separated from each other by the first vertical insulating structure 131. The semiconductor memory device may further include a first core insulating layer 127A between the first channel layer 125A and the first vertical insulating structure 131 and a second core insulating layer 127B between the second channel layer 125B and the first vertical insulating structure 131. Each of the first vertical insulating structure 131, the first core insulating layer 127A, and the second core insulating layer 127B may have a height that defines an opening of an upper end of the channel hole 121.

A first capping doped semiconductor layer 129A of the first channel structure 120A, a second capping doped semiconductor layer 129B of the second channel structure 120B, and the second vertical insulating structure 163 may be disposed at the upper end of the channel hole 121. The first capping doped semiconductor layer 129A may be disposed over the first core insulating layer 127A and the second capping doped semiconductor layer 129B may be disposed over the second core insulating layer 127B. The first capping doped semiconductor layer 129A and the second capping doped semiconductor layer 129B may be separated from each other by the second vertical insulating structure 163.

The first channel layer 125A may extend between the first memory layer 123A and the first capping doped semiconductor layer 129A and contact the first capping doped semiconductor layer 129A. The second channel layer 125B may extend between the second memory layer 123B and the second capping doped semiconductor layer 129B and contact the second capping doped semiconductor layer 129B.

The first capping doped semiconductor layer 129A and the second capping doped semiconductor layer 129B may include a semiconductor material including at least one of an n-type impurity and a p-type impurity. According to an embodiment, the first capping doped semiconductor layer 129A and the second capping doped semiconductor layer 129B may include an n-type impurity as a majority carrier. Ends of the first channel layer 125A and the second channel layer 125B that are respectively adjacent to the first capping doped semiconductor layer 129A and the second semiconductor layer 129B may be respectively doped with the same impurity as the first capping doped semiconductor layer 129A and the second capping doped semiconductor layer 129B.

At least one insulating layer and an etch stop layer 167 may be disposed between the gate stacked structure GST and the plurality of bit lines BL. According to an embodiment, a first insulating layer 165 may be disposed over the gate stacked structure GST and the etch stop layer 167 may be disposed over the first insulating layer 165. In addition, an interposing insulating layer 151 may be disposed between the first insulating layer 165 and the gate stacked structure GST.

The interposing insulating layer 151 may include a plurality of channel contact holes 153. The plurality of channel contact holes 153 may correspond to the plurality of channel holes 121 in a one-to-one manner. The plurality of pairs of the first channel contact 161A and the second channel contact 161B may correspond to the plurality of channel contact holes 153 in a one-to-one manner. The first channel contact 161A and the second channel contact 161B of each of the plurality of pairs may be arranged to be spaced apart from each other in the second direction DR2 in the corresponding channel contact hole 153. The channel contact hole 153 may extend to overlap with the corresponding pair of the first channel structure 120A and the second channel structure 120B. The first channel contact 161A and the second channel contact 161B of each of the plurality of pairs may be arranged to be spaced apart from each other in the second direction DR2 in the corresponding channel contact hole 153. The second vertical insulating structure 163 may extend into a part of the channel contact hole 153 which is between the first channel contact 161A and the second channel contact 161B.

The etch stop layer 167 may include a plurality of trenches 167T that extend in the diagonal direction DR4 and are parallel to each other. Each of the plurality of trenches 167T may overlap with two or more pairs of the first channel structure 120A and the second channel structure 120B that are arranged in the diagonal direction DR4 and two or more pairs of the first channel contact 161A and the second channel contact 161B corresponding to the two or more pairs of the first and second channel structures 120A and 120B.

The plurality of bit lines BL may be disposed in a second insulating layer 169. The second insulating layer 169 may include a horizontal portion 169HP over the etch stop layer 167 and a plurality of protrusions 169PP that extend into the plurality of trenches 167T from the horizontal portion 169HP. Each of the plurality of bit lines BL may overlap with two or more pairs of the first channel structure 120A and the second channel structure 120B that are arranged in the second direction DR2 and two or more pairs of the first channel contact 161A and the second channel contact 161B corresponding to the two or more pairs of the first and second channel structures 120A and 120B.

The first bit line BL1 and the second bit line BL2 may overlap with the first channel structure 120A and the second channel structure 120B of each of the plurality of pairs and the first channel contact 161A and the second channel contact 161B of a pair corresponding to each of the plurality of pairs of the first and the second channel structures 120A and 120B. Each of the plurality of trenches 167T may include a part that overlaps with the first bit line BL1 and the second bit line BL2. A first bit line contact hole 171A may be disposed in an overlapping part of the first bit line BL1 and the trench 167T corresponding thereto and a second bit line contact hole 171B may be disposed in an overlapping part of the second bit line BL2 and the trench 167T corresponding thereto. The first bit line contact hole 171A and the second bit line contact hole 171B may pass through the first insulating layer 165. The first bit line contact 177A and the second bit line contact 177B may be disposed in the first bit line contact hole 171A and the second bit line contact hole 171B, respectively.

The first bit line contact 177A may extend towards the first channel structure 120A from the first bit line BL1 and may be connected to the first channel contact 161A. The second bit line contact 177B may extend towards the second channel structure 120B from the second bit line BL2 and may be connected to the second channel contact 161B.

The protrusion 169PP of the second insulating layer 169 may include a part interposed between the first bit line contact 177A and the second bit line contact 177B and a part interposed between the first bit line BL1 and the second bit line BL2.

The etch stop layer 167 is an intermediate layer positioned between the first and second insulating layers 165 and 169. The etch stop layer 167 may serve as an etching barrier when an etching process for forming the first bit line contact hole 171A at the overlapping part of the trench 167T and the first bit line BL1 and the second bit line contact hole 171B at the overlapping part of the trench 167T and the second bit line BL2 is performed. To serve as the etching barrier, the etch stop layer 167 may include an insulating material having etch selectivity with respect to the first insulating layer 165 and the second insulating layer 169. According to an embodiment, the etch stop layer 167 may include a silicon nitride and the first insulating layer 165 and the second insulating layer 169 may include a silicon oxide. A silicon nitride has higher relative dielectric constant than a silicon oxide. According to an embodiment, the second insulating layer 169, which has relatively lower relative dielectric constant, may be disposed in the trench 167T of the etch stop layer 167. Accordingly, according to an embodiment, parasitic capacitance between the first bit line BL1 and the second bit line BL2, between the first bit line contact 177A and the second bit line contact 177B, between the first bit line BL1 and the second bit line contact 177B, and between the second bit line BL2 and the first bit line contact 177A may be decreased as compared to an embodiment in which the trench 167T is excluded from the etch stop layer 167.

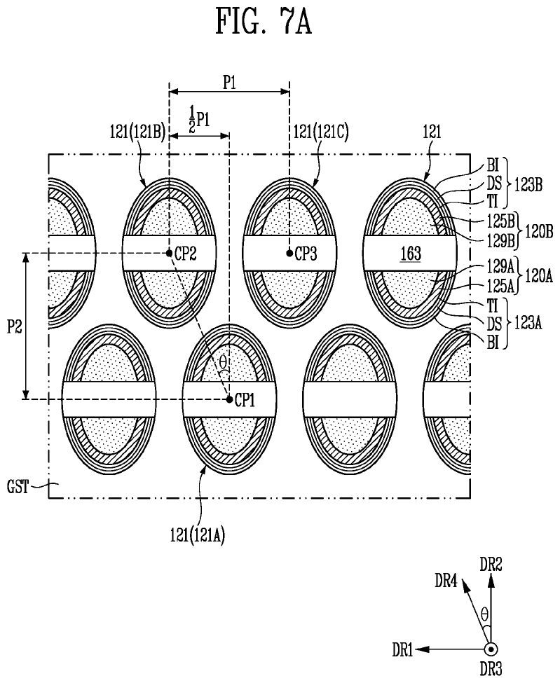

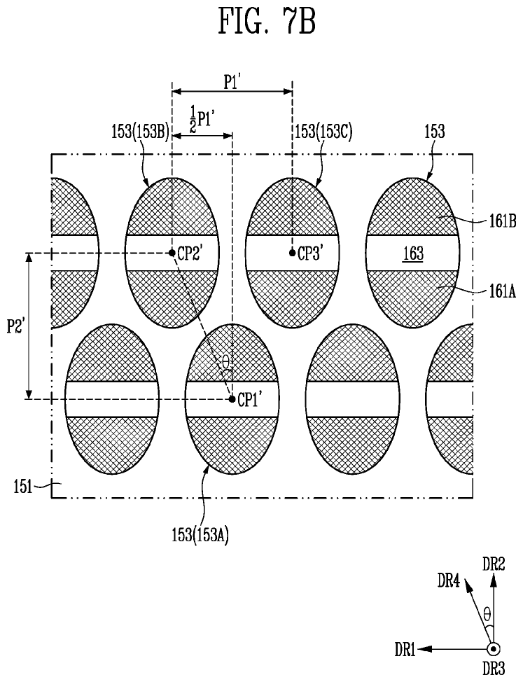

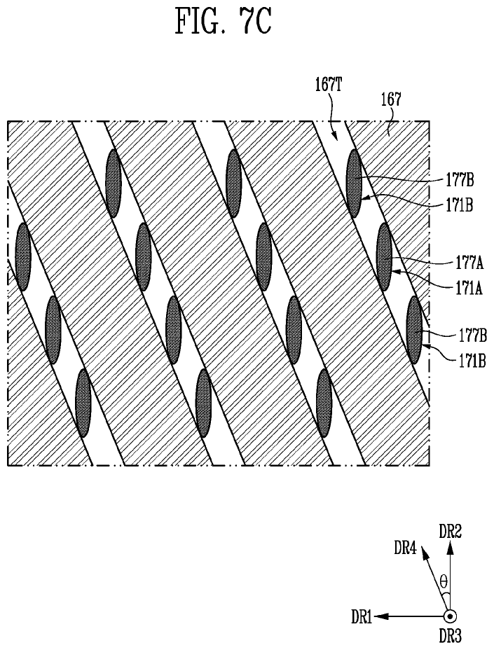

FIGS. 7A, 7B, and 7C are plan views illustrating layouts of a semiconductor memory device shown in FIG. 4 at different depths.

FIG. 7A illustrates a layout of the plurality of channel holes 121 in the same plane.

Referring to FIG. 7A, the plurality of channel holes 121 may be arranged in a plurality of rows and the plurality of channel holes 121 of each row may be arranged in the first direction DR1. The plurality of channel holes 121 in neighboring rows may be arranged such that central regions of the plurality of channel holes 121 in a row are not aligned with central regions of the plurality of channel holes 121 in a neighboring row. Central regions of the plurality of channel holes 121 in the same row may be arranged in a line extending in the first direction DR1.

Arrangement pitch P1 of the plurality of channel holes 121 in the first direction DR1 and arrangement pitch P2 of the plurality of channel holes 121 in the second direction DR2 may be designed such that θ in [Equation 1] below has a value between 10° and 45° considering alignment margins and integration density of the first bit line contact holes 171A and the second bit line contact holes 171B shown in FIG. 7C.

$$θ = {tan}^{- 1} [ \frac{( 1 / 2 ) P 1}{P 2} ] \qquad [ Equation 1 ]$$

The plurality of channel holes 121 may include a first channel hole 121A in a first row and a second channel hole 121B and a third channel hole 121C in a second row that are adjacent to the first channel hole 121A. The second channel hole 121B and the third channel hole 121C may be defined to be adjacent to each other in the first direction DR1. A center point CP1 of the first channel hole 121A may be disposed in the first row at a position corresponding to the center of a connection line between a center point CP2 of the second channel hole 121B and a center point CP3 of the third channel hole 121C.

The second vertical insulating structure 163 may extend between the first memory layer 123A and the second memory layer 123B from between the first channel structure 120A and the second channel structure 120B. Similarly, the first vertical insulating structure 131 shown in FIGS. 6B and 6C may extend between the first memory layer 123A and the second memory layer 123B from between the first channel structure 120A and the second channel structure 120B.

Each of the first memory layer 123A and the second memory layer 123B may include a tunnel insulating layer TI between the corresponding channel structure and the gate stacked structure GST, a data storage layer DS between the tunnel insulating layer TI and the gate stacked structure GST, and a blocking insulating layer BI between the data storage layer DS and the gate stacked structure GST. The data storage layer DS may include a material layer capable of storing data changed by using Fowler-Nordheim tunneling. The data storage layer DS may include various materials, for example, a charge trap layer. The charge trap layer may include a silicon nitride layer. However, embodiments of the present disclosure are not limited thereto, and the data storage layer DS may include a phase-change material, nanodots, or the like. The blocking insulating layer BI may include an insulating material capable of blocking charges. The tunnel insulating layer TI may include a silicon oxide layer enabling charge tunneling.

FIG. 7B is a diagram illustrating a layout of the plurality of channel contact holes 153 in the same plane.

Referring to FIG. 7B, the plurality of channel contact holes 153 may be arranged in a plurality of rows in the same manner as the plurality of channel holes 121 shown in FIG. 7A. For example, respective center points CP1′, CP2′, and CP3′ of a first channel contact hole 153A, a second channel contact hole 153B, and a third channel contact hole 153C that neighbor each other may be arranged in the same manner as the center points of the first, second, and third channel holes 121A, 121B, and 121C shown in FIG. 7A.

Arrangement pitch P1′ of the plurality of channel contact holes 153 in the first direction DR1 and arrangement pitch P2′ of the plurality of channel contact holes 153 in the second direction DR2 may be designed such that θ in [Equation 2] below has a value between 10° and 45° considering alignment margins and integration density of the first bit line contact holes 171A and the second bit line contact holes 171B shown in FIG. 7C.

$$θ = {tan}^{- 1} [ \frac{( 1 / 2 ) P {1}^{′}}{P {2}^{′}} ] \qquad [ Equation 2 ]$$

A value of 0 in each of [Equation 1] and [Equation 2] respectively described with reference to FIGS. 7A and 7B may correspond to an angle that is formed by an axis along the second direction DR2 and an axis along the diagonal direction DR4.

FIG. 7C is a diagram illustrating a layout of the trenches 167T of the etch stop layer 167, the first bit line contacts 177A, and the second bit line contacts 177B in the same plane.

Referring to FIG. 7C, the diagonal direction DR4 may be a direction in which the trench 167T extends, the first bit line contacts 177A and the second bit line contacts 177B are arranged, and the first bit line contact holes 171A and the second bit line contact holes 171B are arranged.

However, the direction in which the trench 167T extends is not limited to the diagonal direction DR4 and may be changed.

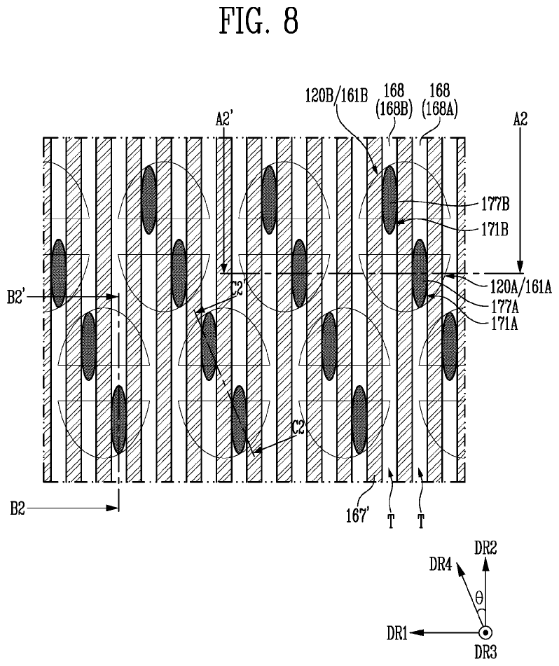

FIG. 8 is a plan view illustrating an arrangement of an etch stop layer and a plurality of bit line contacts of a semiconductor memory device according to an embodiment. Hereinafter, a detailed description of components already described in the embodiments shown in FIGS. 4 to 7C will be omitted for the sake of brevity.

Referring to FIG. 8, an etch stop layer 167′ may extend in the second direction DR2 and may be penetrated by a plurality of trenches T that are parallel to each other. The first bit line contact 177A and the second bit line contact 177B of each of the plurality of pairs may be respectively disposed in the trenches T that neighbor each other in the first direction DR1. The first bit line contact hole 171A and the second bit line contact hole 171B of each of the plurality of pairs may also be respectively disposed in the trenches T that neighbor each other in the first direction DR1. The first bit line contact 177A and the second bit line contact 177B may be aligned with each other in the diagonal direction DR4. An angle (θ) that is formed by an axis extending in the diagonal direction DR4 and an axis extending in the second direction DR2 may be between 10° and 45° as described above with reference to FIGS. 7A, 7B, and 7C.

A plurality of insulating lines 168 may be respectively disposed in the plurality of trenches T. The plurality of insulating lines 168 may include a first insulating line 168A and a second insulating line 168B that neighbor each other in the first direction DR1. The first insulating line 168A and the second insulating line 168B may extend in the second direction DR2 to overlap with the first channel structure 120A and the second channel structure 120B that form a pair and the first channel contact 161A and the second channel contact 161B that form a pair.

The first bit line contact 177A may pass through the first insulating line 168A in an overlapping part of the first insulating line 168A and the first channel structure 120A. The second bit line contact 177B may pass through the second insulating line 168B in an overlapping part of the second insulating line 168B and the second channel structure 120B.

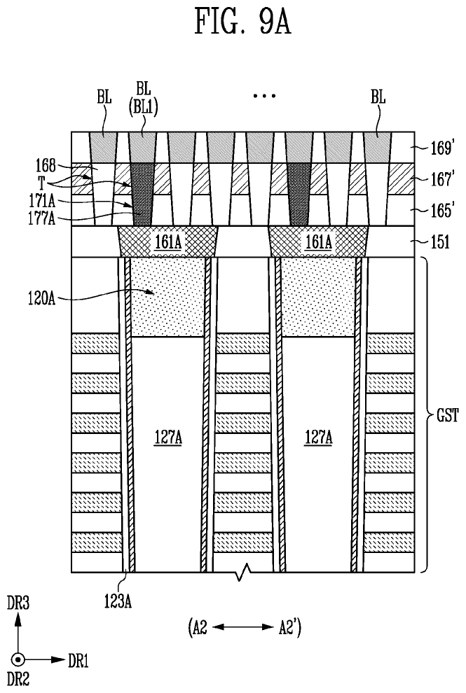

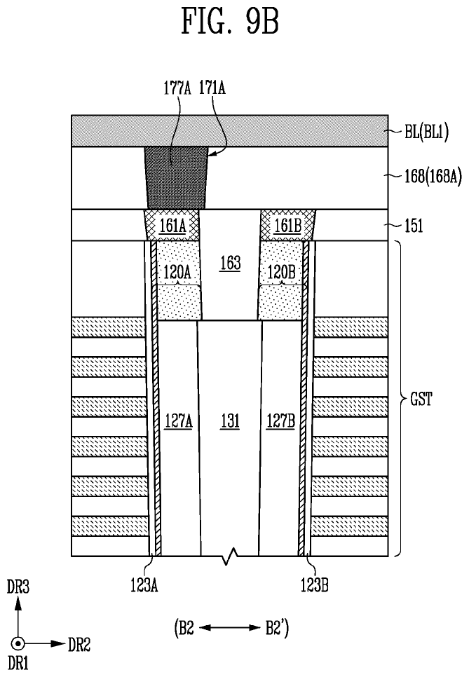

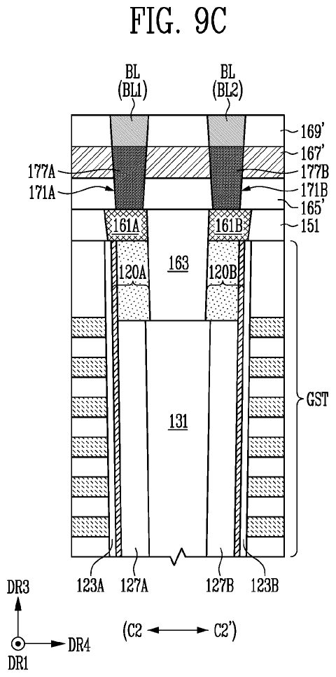

FIGS. 9A, 9B, and 9C are cross-sectional diagrams of a semiconductor memory device which are taken along lines A2-A2′, B2-B2′, and C2-C2′ of FIG. 8, respectively.

Referring to FIGS. 8, 9A, 9B, and 9C, the semiconductor memory device may include the gate stacked structure GST, the first channel structure 120A, the second channel structure 120B, the first memory layer 123A, the second memory layer 123B, the first core insulating layer 127A, the second core insulating layer 127B, the first vertical insulating structure 131, the second vertical insulating structure 163, and the interposing insulating layer 151 as described above with reference to FIGS. 5, 6A, 6B, and 6C. A first insulating layer 165′ may be disposed over the interposing insulating layer 151.

The plurality of trenches T may pass through not only the etch stop layer 167′ but also the first insulating layer 165′. According to the above-described structure, the plurality of insulating lines 168 may be regarded as passing through not only the etch stop layer 167′ but also the first insulating layer 165′.

The first bit line contact hole 171A and the first bit line contact 177A corresponding to the first insulating line 168A may pass through the first insulating line 168A and the first insulating layer 165′ in an overlapping part of the first channel structure 120A and the first insulating line 168A. The second bit line contact hole 171B and the second bit line contact 177B corresponding to the second insulating line 168B may pass through the second insulating line 168B and the first insulating layer 165′ in an overlapping part of the second channel structure 120B and the second insulating line 168B.

The plurality of bit lines BL may be respectively disposed over the plurality of the insulating lines 168. The plurality of bit lines BL may include the first bit line BL1 coupled to the first bit line contact 177A and the second bit line BL2 coupled to the second bit line contact 177B.

As described above with reference to FIGS. 5, 6A, 6B, and 6C, the etch stop layer 167′ is an intermediate layer positioned between the first and second insulating layers 165′ and 169′. The etch stop layer 167′ may include an insulating material having etch selectivity with respect to the first insulating layer 165′, the plurality of insulating lines 168, and a second insulating layer 169′. As described above with reference to FIGS. 5, 6A, 6B, and 6C, the etch stop layer 167′ may include a silicon nitride such that the etch stop layer 167′ serves as an etching barrier when an etching process for forming the first bit line contact hole 171A and the second bit line contact hole 171B is performed. In an embodiment, the first insulating layer 165′, the plurality of insulating lines 168, and the second insulating layer 169′ may include an insulating material having lower relative dielectric constant than the etch stop layer 167′ such that parasitic capacitance is reduced as described above with reference to FIGS. 5, 6A, 6B, and 6C. According to an embodiment, the first insulating layer 165′, the plurality of insulating lines 168, and the second insulating layer 169′ may include a silicon oxide.

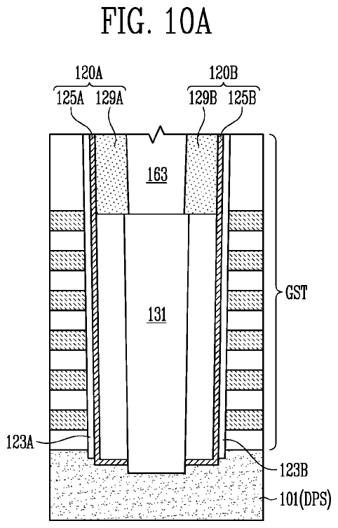

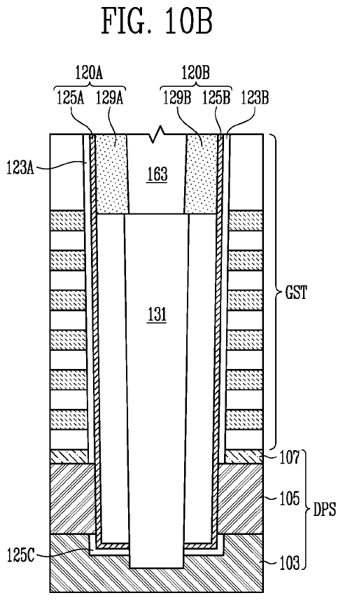

FIGS. 10A and 10B are cross-sectional diagrams illustrating a structure in which a doped semiconductor structure and a channel structure are coupled according to embodiments.

Referring to FIGS. 10A and 10B, the first channel layer 125A of the first channel structure 120A and the second channel layer 125B of the second channel structure 120B may contact the doped semiconductor structure DPS according to embodiments. The doped semiconductor structure DPS may overlap with the gate stacked structure GST. The first vertical insulating structure 131 may be disposed between the second vertical insulating structure 163 and the doped semiconductor structure DPS and may include a bottom surface that contacts the doped semiconductor structure DPS.

The doped semiconductor structure DPS may include at least one of an n-type impurity and a p-type impurity. According to an embodiment, the doped semiconductor structure DPS may include, as a majority carrier, an impurity of which a conductivity type is the same as that of an impurity in the first capping doped semiconductor layer 129A of the first channel structure 120A and in the second capping doped semiconductor layer 129B of the second channel structure 120B. According to another embodiment, the doped semiconductor structure DPS may include a region having an n-type impurity as a majority carrier and a region having a p-type impurity as a majority carrier.

The doped semiconductor structure DPS may contact the first channel layer 125A and the second channel layer 125B by various methods.

Referring to FIG. 10A, the doped semiconductor structure DPS may include at least one semiconductor layer. According to an embodiment, the doped semiconductor structure DPS may include a single semiconductor layer 101. The semiconductor layer 101 may be a monocrystalline semiconductor layer or a polycrystalline semiconductor layer.

The first channel layer 125A and the second channel layer 125B may extend into the doped semiconductor structure DPS and may each include a bottom surface that contacts the doped semiconductor structure DPS.

Referring to FIG. 10B, the doped semiconductor structure DPS may include two or more semiconductor layers. According to an embodiment, the doped semiconductor structure DPS may include a first semiconductor layer 103, a second semiconductor layer 105 over the first semiconductor layer 103, and a third semiconductor layer 107 over the second semiconductor layer 105.

The first channel layer 125A and the second channel layer 125B may pass through the third semiconductor layer 107 and may extend into the first semiconductor layer 103. The second semiconductor layer 105 may contact a part of a sidewall of each of the first channel layer 125A and the second channel layer 125B and extend between the first semiconductor layer 103 and the third semiconductor layer 107.

The first memory layer 123A or the second memory layer 123B may extend from between the corresponding channel layer 125A or 125B and the gate stacked structure GST to between the corresponding channel layer 125A or 125B and the third semiconductor layer 107. A lower memory layer 125C may be interposed between the first semiconductor layer 103 and each of the first channel layer 125A and the second channel layer 125B. The lower memory layer 125C may include the same material layers as the first memory layer 123A and the second memory layer 123B.

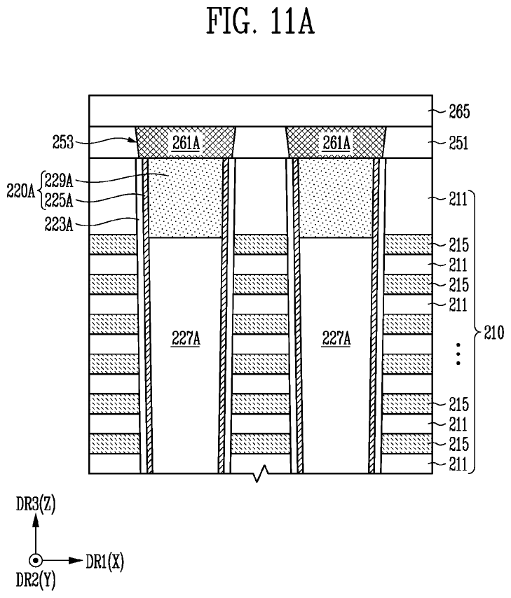

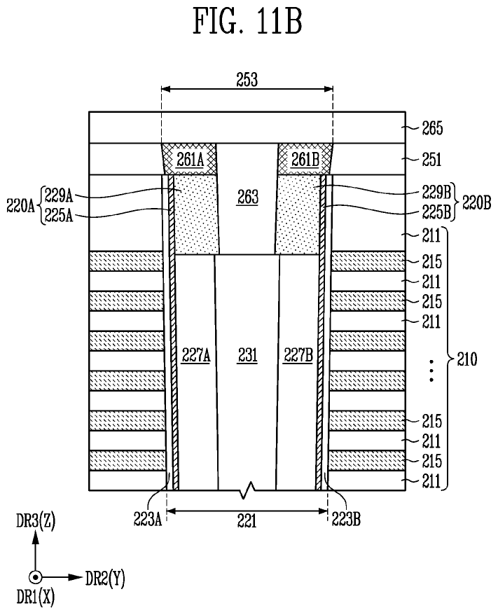

FIGS. 11A, 11B, 12A, 12B, 13A, 13B, 14A, 14B, 15A, 15B, and 15C are diagrams illustrating a method of manufacturing a semiconductor memory device according to an embodiment.

Referring to FIGS. 11A and 11B, a substrate (not shown) including various lower structures may be provided according to embodiments and a memory cell array structure may be formed over the substrate.

The memory cell array structure may include a gate stacked structure 210. The memory cell array structure may also include a first memory layer 223A, a second memory layer 223B, a first channel structure 220A, and a second channel structure 220B in a channel hole 221 that passes through the gate stacked structure 210. The gate stacked structure 210 may include a plurality of layers 211 and 215 having a plate shape that extends in the first direction DR1 and the second direction DR2. The plurality of layers 211 and 215 may include a plurality of interlayer insulating layers 211 and a plurality of conductive layers 215 that are disposed alternately with each other in the third direction DR3 as described above with reference to FIGS. 4, 6A, 6B, and 6C. A first core insulating layer 227A, a second core insulating layer 227B, a first vertical insulating structure 231, and a second vertical insulating structure 263 may be disposed in the channel hole 221.

Forming the above-described memory cell array structure may include forming the plurality of layers 211 and 215, forming the channel hole 221 that passes through the plurality of layers 211 and 215, forming a preliminary memory layer on a sidewall of the channel hole 221, forming a preliminary channel layer on the preliminary memory layer, forming a preliminary core insulating layer in a central region of the channel hole 221 that is opened by the preliminary channel layer, forming the first vertical insulating structure 231 that passes through the preliminary core insulating layer, replacing an upper part of the preliminary core insulating layer and an upper part of the first vertical insulating structure 231 by a preliminary capping doped semiconductor layer, and forming the second vertical insulating structure 263 that passes through the preliminary capping doped semiconductor layer.

The preliminary memory layer may include the blocking insulating layer BI, the data storage layer DS, and the tunnel insulating layer TI shown in FIG. 7A. The preliminary memory layer may be divided into the first memory layer 223A and the second memory layer 223B by the first vertical insulating structure 231.

The first vertical insulating structure 231 may divide the preliminary channel layer into a first channel layer 225A of the first channel structure 220A and a second channel layer 225B of the second channel structure 220B. The first vertical insulating structure 231 may divide the preliminary core insulating layer into the first core insulating layer 227A and the second core insulating layer 227B.

The second vertical insulating structure 263 may divide the preliminary capping doped semiconductor layer into a first capping doped semiconductor layer 229A of the first channel structure 220A and a second capping doped semiconductor layer 229B of the second channel structure 220B. Forming an interposing insulating layer 251 over the gate stacked structure 210, forming a channel contact hole 253 that passes through the interposing insulating layer 251, and forming a conductive material in the channel contact hole 253 may be performed before forming the second vertical insulating structure 263. The conductive material in the channel contact hole 253 may be divided into a first channel contact 261A and a second channel contact 261B by the second vertical insulating structure 263.

The channel hole 221, the first channel structure 220A, and the second channel structure 220B may be formed to correspond to the arrangement described above with reference to FIG. 7A and the channel contact hole 253, the first channel contact 261A, and the second channel contact 261B may be formed to correspond to the arrangement described above with reference to FIG. 7B.

Subsequently, a first insulating layer 265 may be formed over the interposing insulating layer 251.

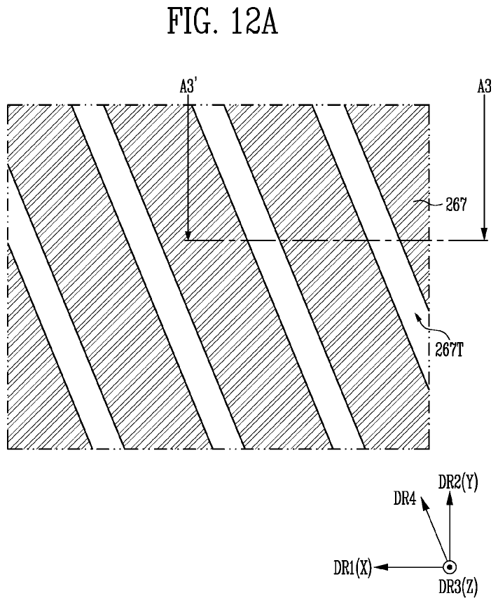

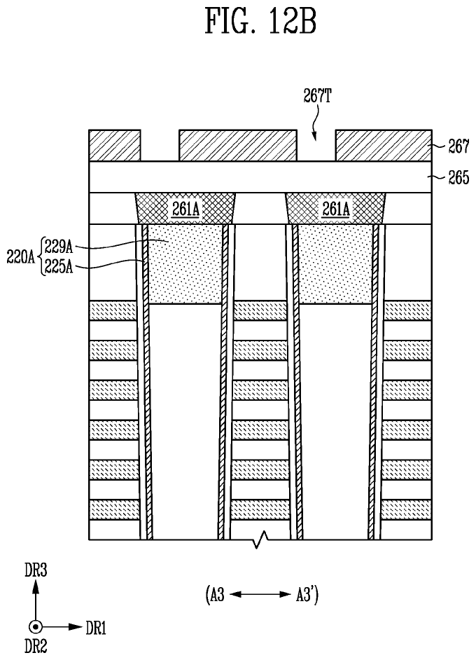

FIG. 12A is a plan view illustrating a step of forming an etch stop layer 267 that includes a first trench 267T and FIG. 12B is a cross-sectional diagram taken along line A3-A3′ of FIG. 12A.

Referring to FIGS. 12A and 12B, the etch stop layer 267 may be formed over the first insulating layer 265. The etch stop layer 267 may include an insulating material having etch selectivity with respect to the first insulating layer 265. According to an embodiment, the first insulating layer 265 may include a silicon oxide and the etch stop layer 267 may include a silicon nitride.

Subsequently, the first trench 267T may be formed by etching the etch stop layer 267. The first trench 267T may extend in the diagonal direction DR4 between the first direction DR1 and the second direction DR2.

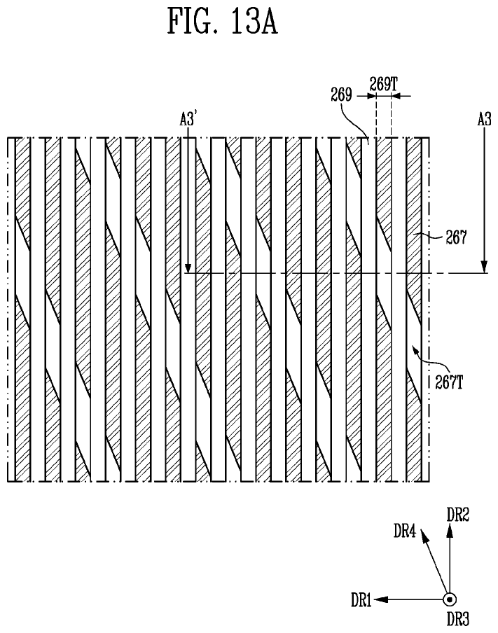

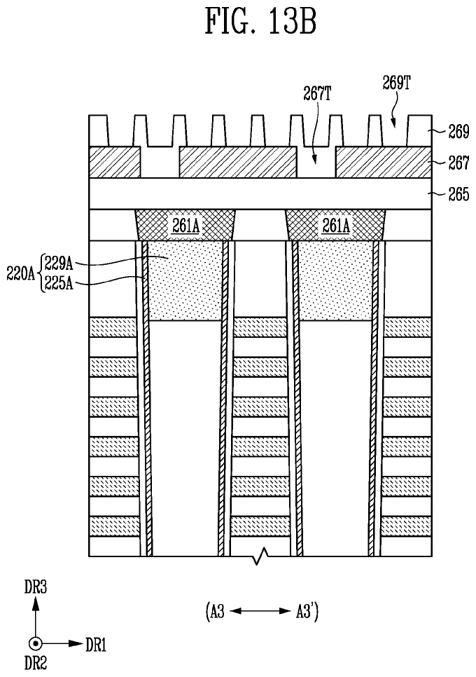

FIG. 13A is a plan view illustrating a step of forming a second insulating layer 269 that includes a plurality of second trenches 269T and FIG. 13B is a cross-sectional diagram taken along line A3-A3′ of FIG. 13A.

Referring to FIGS. 13A and 13B, the second insulating layer 269 may be formed over the etch stop layer 267. The second insulating layer 269 may be formed to fill the first trench 267T. The second insulating layer 269 may include a different material from the etch stop layer 267 and include an insulating material that has lower relative dielectric constant than the etch stop layer 267. According to an embodiment, the second insulating layer 269 may include a silicon oxide.

Subsequently, the plurality of second trenches 269T extending in the second direction DR2 may be formed. The plurality of second trenches 269T may be disposed to be spaced apart from each other in the first direction DR1.

Each of the first trench 267T shown in FIGS. 12A and 12B and the plurality of second trenches 269T shown in FIGS. 13A and 13B may be formed by a photolithography process and an etching process that correspond to each of the first trench 267T and the plurality of second trenches 269T.

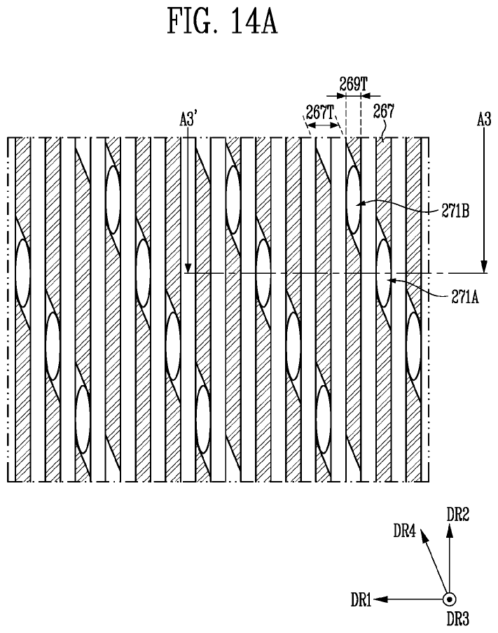

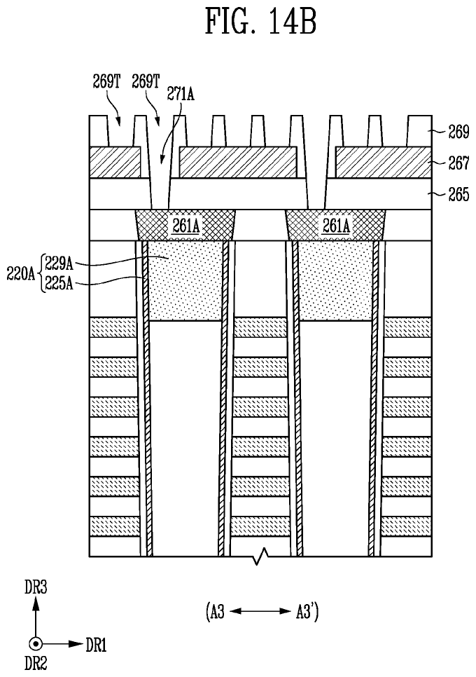

FIG. 14A is a plan view illustrating a step of forming a first bit line contact hole 271A and a second bit line contact hole 271B and FIG. 14B is a cross-sectional diagram taken along line A3-A3′ of FIG. 14A.

Referring to FIGS. 14A and 14B, a part of the second insulating layer 269 in the first trench 267T may be exposed through overlapping parts of the first trench 267T and the plurality of second trenches 269T. An exposed region of the second insulating layer 269 may have a rhombus shape or a parallelogram shape.

Subsequently, the first bit line contact hole 271A and the second bit line contact hole 271B may be formed by etching the exposed region of the second insulating layer 269 and regions of the corresponding first insulating layer 265. The etch stop layer 267 may serve as an etching barrier when the first insulating layer 265 and the second insulating layer 269 are etched. Regions corresponding to edges of a rhombus or a parallelogram may be processed to be rounded due to the effect of etch bias when the first insulating layer 265 and the second insulating layer 269 are etched.

Each of the first bit line contact hole 271A and the second bit line contact hole 271B may overlap with a channel structure corresponding thereto and expose a channel contact corresponding thereto. For example, the first bit line contact hole 271A may overlap with the first channel structure 220A and expose the first channel contact 261A.

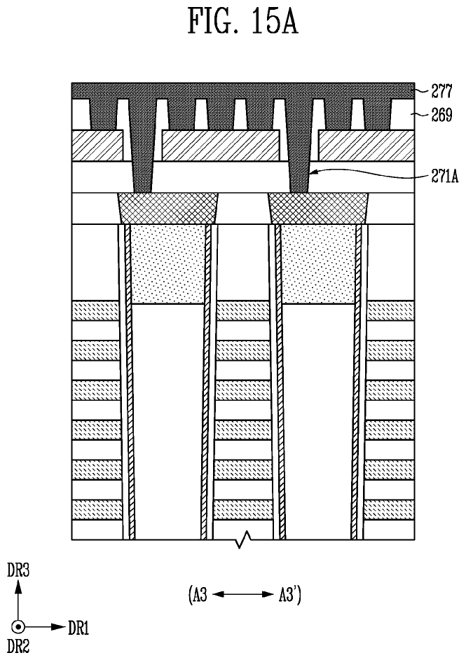

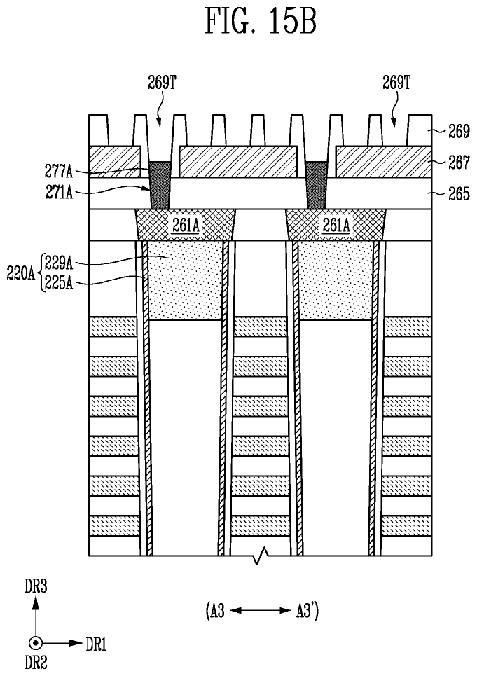

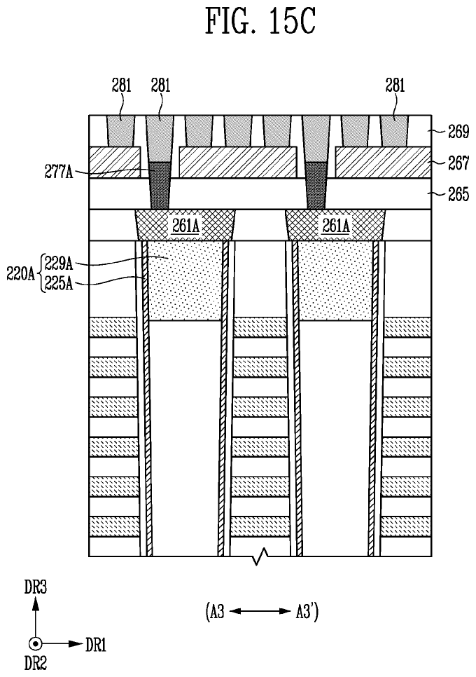

FIGS. 15A, 15B, and 15C are cross-sectional diagrams illustrating respective processes of forming a bit line contact and forming a plurality of bit lines.

Referring to FIG. 15A, a conductive layer 277 may be formed to fill the first bit line contact hole 271A and the second bit line contact hole 271B shown in FIGS. 14A and 14B.

Referring to FIG. 15B, bit line contacts may be formed and the plurality of second trenches 269T may be opened by removing the conductive layer 277 shown in FIG. 15A by an etching process such as an etch-back process.

The bit line contacts may include a first bit line contact 277A filling the first bit line contact hole 271A and a second bit line contact filling the second bit line contact hole 271B shown in FIG. 14A.

Referring to FIG. 15C, after a conductive layer is formed to fill the plurality of second trenches 269T shown in FIG. 15B, a planarization process may be performed to expose the second insulating layer 269. Accordingly, a plurality of bit lines 281 filling the plurality of second trenches 269T shown in FIG. 15B may be formed.

The semiconductor memory device described above with reference to FIGS. 4, 5, 6A, 6B, 6C, 7A, 7B, and 7C may be formed using the processes described above with reference to FIGS. 11A to 15C.

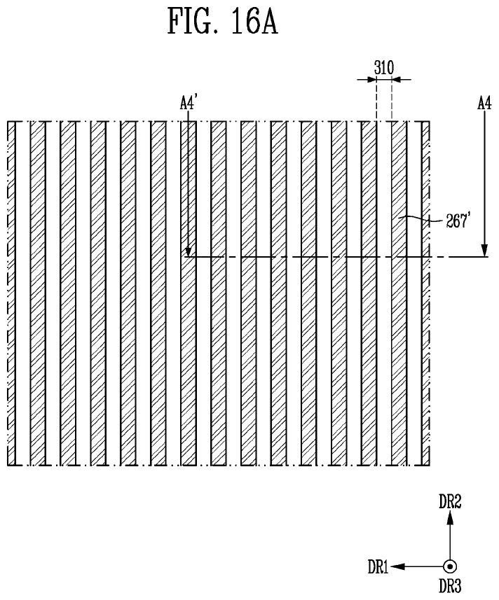

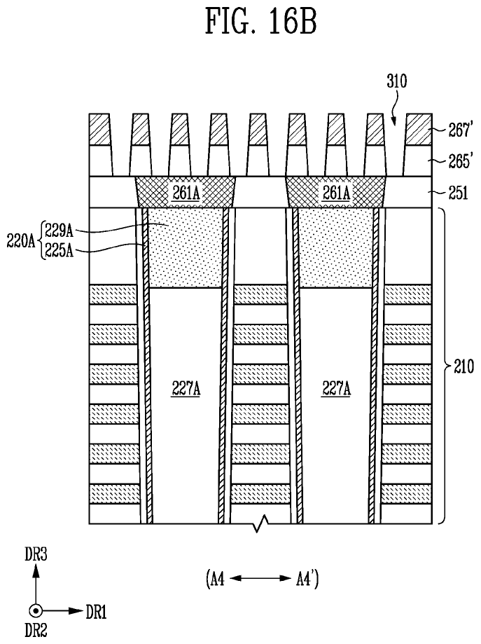

FIGS. 16A, 16B, 17A, 17B, 18A, 18B, 19A, and 19B are diagrams illustrating a method of manufacturing a semiconductor memory device according to an embodiment.

FIG. 16A is a plan view illustrating a step of forming a plurality of first trenches 310 and FIG. 16B is a cross-sectional diagram taken along line A4-A4′ of FIG. 16A.

The processes described above with reference to FIGS. 11A and 11B may precede a process illustrated in FIGS. 16A and 16B. Accordingly, the gate stacked structure 210, the first memory layer 223A, the second memory layer 223B, the first channel structure 220A, the second channel structure 220B, the first core insulating layer 227A, the second core insulating layer 227B, the first vertical insulating structure 231, the second vertical insulating structure 263, the first channel contact 261A, and the second channel contact 261B that are described above with reference to FIGS. 11A and 11B may be formed.

Referring to FIGS. 16A and 16B, a first insulating layer 265′ may be formed over the memory cell array that is provided by the processes described above with reference to FIGS. 11A and 11B. The first insulating layer 265′ may be formed over the interposing insulating layer 251 as described above with reference to FIGS. 11A and 11B.

Subsequently, an etch stop layer 267′ may be formed over the first insulating layer 265′. The etch stop layer 267′ may include a material which is selected considering etch selectivity as described above with reference to FIGS. 12A and 12B. Subsequently, the plurality of first trenches 310 may be formed by etching the etch stop layer 267′ and the first insulating layer 265′. The plurality of first trenches 310 may extend in the second direction DR2 to expose the first channel contact 261A and the second channel contact 261B shown in FIG. 11B. The plurality of first trenches 310 may be spaced apart from each other in the first direction DR1.

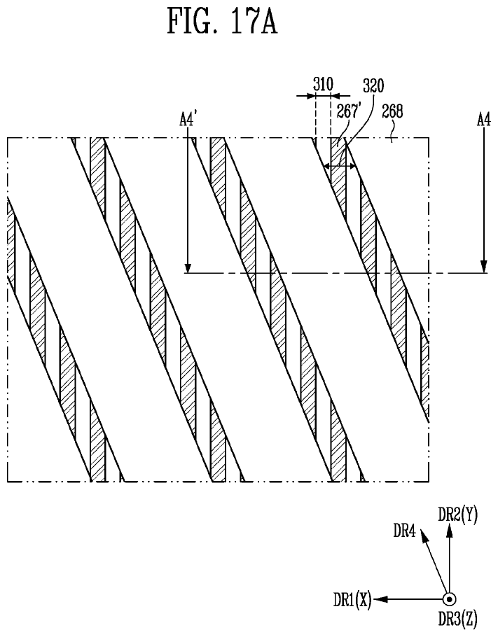

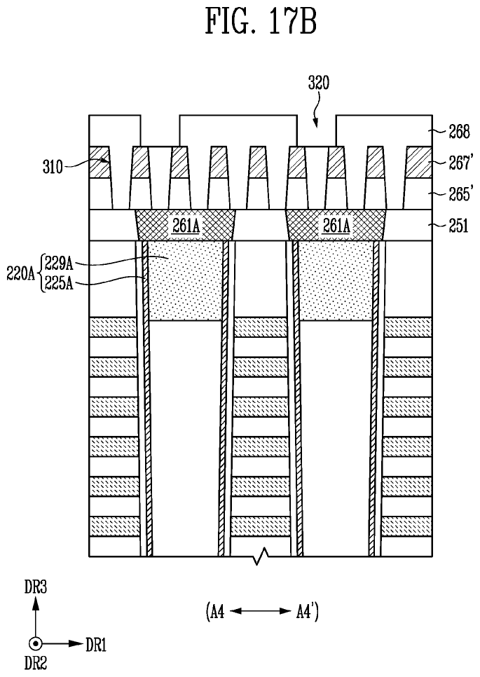

FIG. 17A is a plan view illustrating a step of forming a second trench 320 and FIG. 17B is a cross-sectional diagram taken along line A4-A4′ of FIG. 17A.

Referring to FIGS. 17A and 17B, a gap-fill insulating layer 268 may be formed over the etch stop layer 267′ to fill the plurality of first trenches 310. The gap-fill insulating layer 268 may include an insulating material having lower relative dielectric constant than the etch stop layer 267′. According to an embodiment, the gap-fill insulating layer 268 may include a silicon oxide.

Subsequently, the second trench 320 may be formed by etching the gap-fill insulating layer 268. The second trench 320 may extend in the diagonal direction DR4 between the first direction DR1 and the second direction DR2.

Each of the first trench 310 shown in FIGS. 16A and 16B and the second trench 320 shown in FIGS. 17A and 17B may be formed by a photolithography process and an etching process that correspond to each of the first trench 310 and the second trench 320.

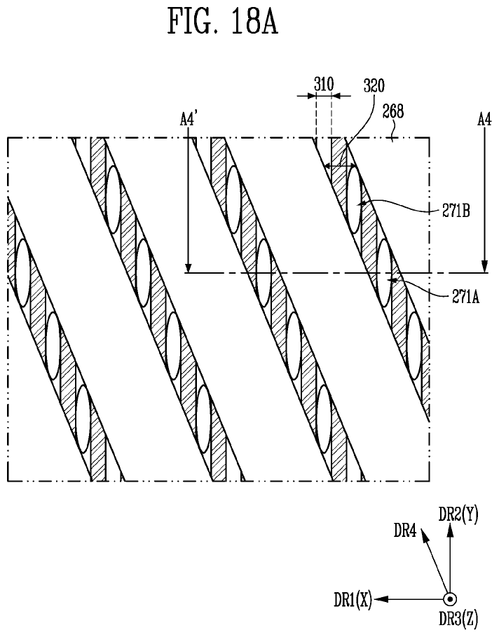

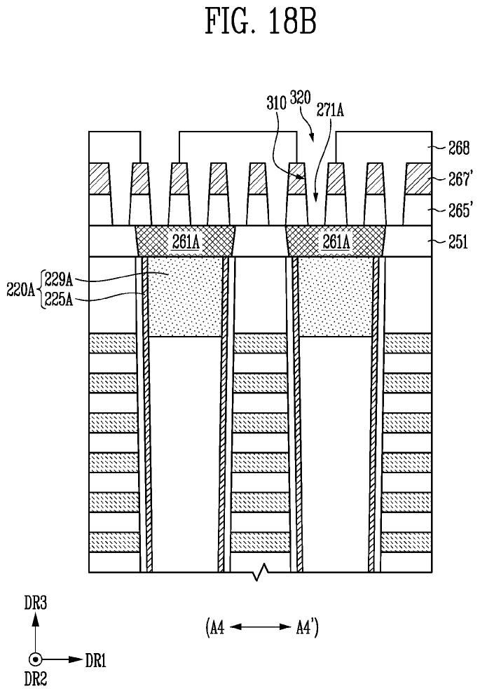

FIG. 18A is a plan view illustrating a step of forming the first bit line contact hole 271A and the second bit line contact hole 271B and FIG. 18B is a cross-sectional diagram taken along line A4-A4′ of FIG. 18A.

Referring to FIGS. 18A and 18B, a part of the gap-fill insulating layer 268 in the first trench 310 may be exposed in a rhombus or parallelogram shape through overlapping parts of the first trench 310 and the second trench 320.

Subsequently, some regions of the gap-fill insulating layer 268 may be further etched to have a greater depth than other regions through the overlapping parts of the first trench 310 and the second trench 320. Accordingly, the first bit line contact hole 271A and the second bit line contact hole 271B may be formed. The etch stop layer 267′ may serve as an etching barrier when some regions of the gap-fill insulating layer 268 are etched through the overlapping parts of the first trench 310 and the second trench 320. Regions corresponding to edges of a rhombus or a parallelogram may be processed to be rounded due to the effect of etch bias when some regions of the gap-fill insulating layer 268 are etched through the overlapping parts of the first trench 310 and the second trench 320.

Each of the first bit line contact hole 271A and the second bit line contact hole 271B may overlap with a channel structure corresponding thereto and expose a channel contact corresponding thereto. For example, the first bit line contact hole 271A may overlap with the first channel structure 220A and expose the first channel contact 261A.

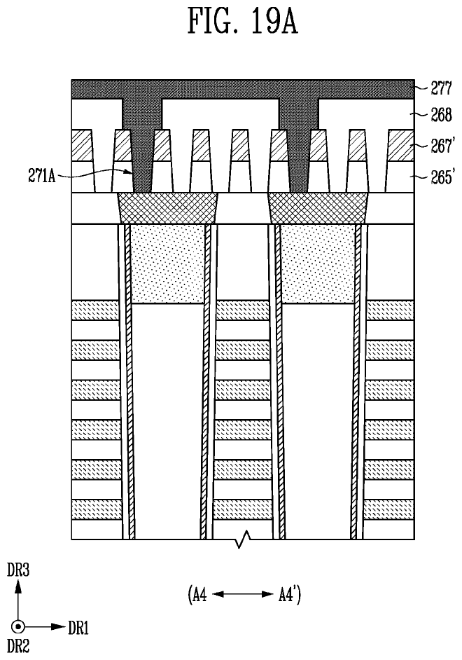

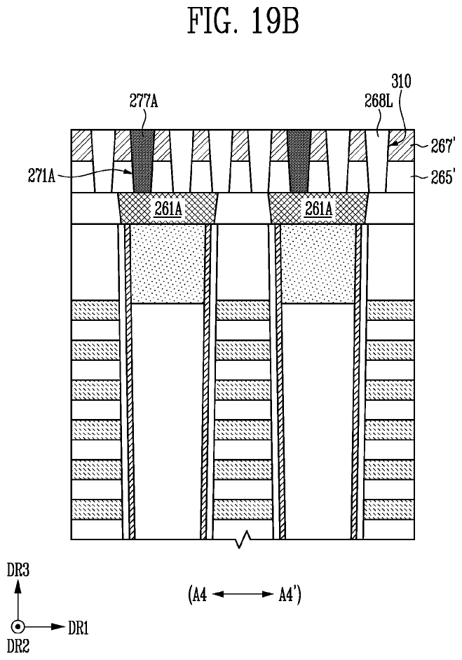

FIGS. 19A and 19B are cross-sectional diagrams illustrating respective processes of forming a bit line contact.

Referring to FIG. 19A, the conductive layer 277 may be formed to fill the first bit line contact hole 271A and the second bit line contact hole 271B shown in FIG. 18A.

Referring to FIG. 19B, bit line contacts may be formed by removing the conductive layer 277 shown in FIG. 19A by a planarization process to expose the etch stop layer 267′. The bit line contacts may include the first bit line contact 277A filling the first bit line contact hole 271A and the second bit line contact filling the second bit line contact hole 271B shown in FIG. 18A. A subsequent process for forming a second insulating layer and a plurality of bit lines may be performed.

The semiconductor memory device described above with reference to FIGS. 8, 9A, 9B, and 9C may be formed using the processes described above with reference to FIGS. 16A to 19B.

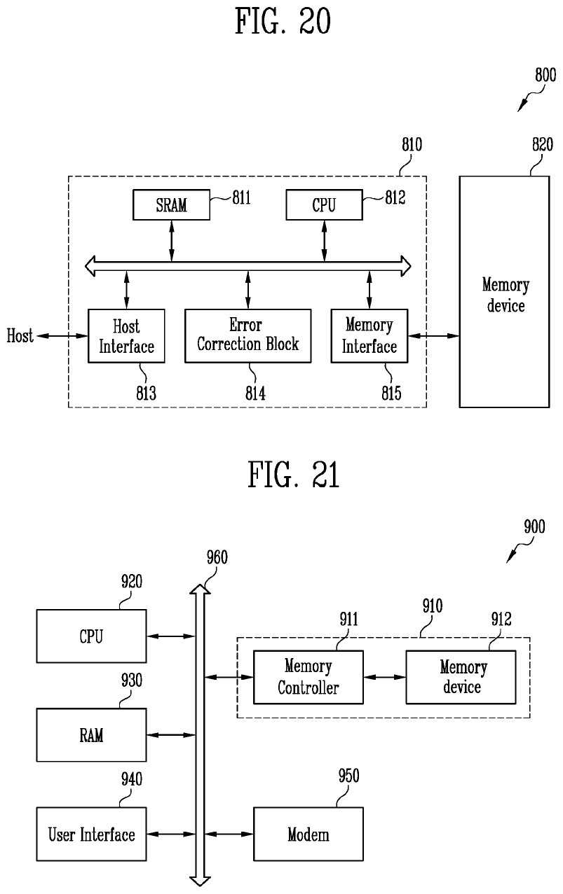

FIG. 20 is a block diagram illustrating a configuration of a memory system 800 according to an embodiment.

Referring to FIG. 20, the memory system 800 may include a memory device 820 and a memory controller 810.

The memory device 820 may be a multi-chip package including a plurality of flash memory chips. The memory device 820 may include, in an embodiment, a first channel structure, a second channel structure, an etch stop layer having a trench that overlaps with the first and second channel structures, a first bit line contact and a second bit line contact that are arranged in a diagonal direction with respect to a direction in which the first and second channel structures are arranged and are coupled to the first channel structure and the second channel structure, respectively, and an insulating material in the trench.

The memory controller 810 may be configured to control the memory device 820 and may include Static Random Access Memory (SRAM) 811, a Central Processing Unit (CPU) 812, a host interface 813, an error correction block 814, and a memory interface 815. The SRAM 811 may serve as operating memory of the CPU 812, the CPU 812 may perform general control operations for data exchange of the memory controller 810, and the host interface 813 may include a data exchange protocol of a host accessing the memory system 800. The error correction block 814 may detect and correct errors included in data read from the memory device 820. The memory interface 815 may interface with the memory device 820. The memory controller 810 may further include Read Only Memory (ROM) for storing code data for interfacing with the host.

The memory system 800 having the above-described configuration may be a Solid-State Drive (SSD) or a memory card in which the memory device 820 and the memory controller 810 are combined. For example, when the memory system 800 is an SSD, the memory controller 810 may communicate with an external device (e.g., the host) through one of various interface protocols including a Universal Serial Bus (USB), a MultiMedia Card (MMC), Peripheral Component Interconnect Express (PCIe), Serial Advanced Technology Attachment (SATA), Parallel Advanced Technology Attachment (PATA), a Small Computer System Interface (SCSI), an Enhanced Small Disk Interface (ESDI), and Integrated Drive Electronics (IDE).

FIG. 21 is a block diagram illustrating a configuration of a computing system 900 according to an embodiment.

Referring to FIG. 21, the computing system 900 may include a CPU 920, Random Access Memory (RAM) 930, a user interface 940, a modem 950, and a memory system 910 that are electrically coupled to a system bus 960. When the computing system 900 is a mobile device, a battery for supplying an operating voltage to the computing system 900 may be further included, and an application chipset, an image processor, mobile DRAM, and the like may be further included.

The memory system 910 may include a memory device 912 and a memory controller 911. The memory device 912 may be configured in the same manner as the memory device 820 described above with reference to FIG. 20. The memory controller 911 may be configured in the same manner as the memory controller 810 described above with reference to FIG. 20.

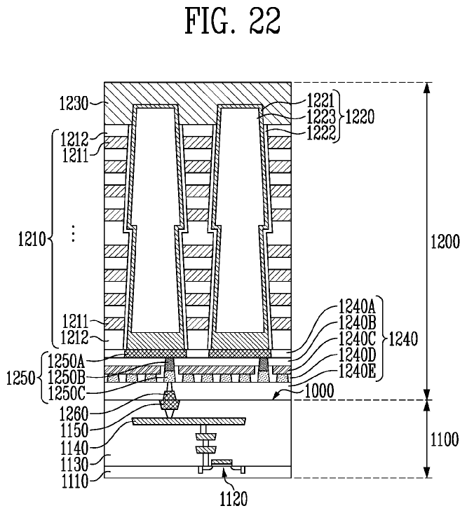

FIG. 22 is a diagram illustrating the structure of a semiconductor memory device according to an embodiment.

Referring to FIG. 22, the semiconductor memory device may include a first semiconductor structure 1100 and a second semiconductor structure 1200. A bonding interface 1000 may be located in the semiconductor memory device, and the first semiconductor structure 1100 is distinguished from the second semiconductor structure 1200 by the bonding interface 1000. The second semiconductor structure 1200 may be disposed over or under the first semiconductor structure 1100. The first semiconductor structure 1100 may include a peripheral circuit structure, and the second semiconductor structure 1200 may include a memory cell array.

The first semiconductor structure 1100 may include a substrate 1110, a transistor 1120, a first insulator 1130, a first interconnection structure 1140, and a first conductive bonding pad 1150. The transistor 1120 may be included in the peripheral circuit structure. The peripheral circuit structure may include a row decoder, a page buffer, an input/output circuit, a logic circuit, and the like. The first interconnection structure 1140 may be disposed in the first insulator 1130 and may include a via, a wiring line, and the like. The first conductive bonding pad 1150 may be disposed at the bonding interface 1000 and may be electrically connected to the peripheral circuit structure through the first interconnection structure 1140.

The second semiconductor structure 1200 may include a gate stacked structure 1210, a cell pillar 1220, a source structure 1230, a second insulator 1240, a second interconnection structure 1250, and a second conductive bonding pad 1260. The gate stacked structure 1210 may include gate lines 1211 alternately stacked with insulating layers 1212. The gate lines 1211 correspond to the conductive layers described above with reference to FIGS. 6A to 6C. The insulating layers 1212 correspond to the interlayer insulating layers described above with reference to FIGS. 6A to 6C. The source structure 1230 may be disposed over the gate stacked structure 1210. The source structure 1230 may comprise the doped semiconductor structure described above with reference FIG. 10A. The cell pillar 1220 may be formed in a channel hole extending through the gate stacked structure 1210. The cell pillar 1220 may include channel structures spaced apart from each other in the same channel hole, as described above with reference to FIG. 4. The cell pillar 1220 may include a channel structure 1221, a memory layer 1222, and/or a core insulating layer 1223. The channel structure 1221 may extend through the gate stacked structure 1210 and may be connected to the source structure 1230. The second interconnection structure 1250 may be disposed in the second insulator 1240. The second insulator 1240 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 1240 may include an interposing insulating layer 1240A, a first insulating layer 1240B, an etch stop layer 1240C, and a second insulating layer 1240D corresponding to the configuration of FIGS. 6A to 6C. Furthermore, the second insulator 1240 may further include a third insulating layer 1240E positioned between the second insulating layer 1240D and the first semiconductor structure 1100. The second interconnection structure 1250 may include a via, a wiring line, and the like. For example, the second interconnection structure 1250 may include a channel contact 1250A, a bit line contact 1250B, and a bit line 1250C, as configured in FIGS. 6A to 6C or FIGS. 9A to 9C. The second conductive bonding pad 1260 may be disposed at the bonding interface 1000 and may be electrically connected to the memory cell array through the second interconnection structure 1250.

The first conductive bonding pad 1150 may be electrically connected to the second conductive bonding pad 1260 at the bonding interface 1000, and the memory cell array may be electrically connected to the peripheral circuit structure through the first conductive bonding pad 1150 and the second conductive bonding pad 1260.

The semiconductor memory device may be manufactured using a method such as hybrid bonding, metal bonding, insulator bonding, or semiconductor bonding. For example, the semiconductor memory device may be manufactured by manufacturing a first wafer including the peripheral circuit structure and a second wafer including the memory cell array, and bonding the first wafer to the second wafer.

Some of the first semiconductor structure 1100 and the second semiconductor structure 1200 may be formed after the first wafer is bonded to the second wafer. For example, the second wafer including a substrate, the gate stacked structure 1210, and the cell pillar 1220 may be formed, flipped, and bonded to the first wafer including the transistor 1120. Subsequently, a rear surface of the gate stacked structure 1210 may be exposed by removing the substrate of the second wafer, and the channel structure 1221 may be exposed by etching the memory layer 1222 of the cell pillar 1220 protruding from the rear surface of the gate stacked structure 1210. The source structure 1230 may be formed on the rear surface of the gate stacked structure 1210.

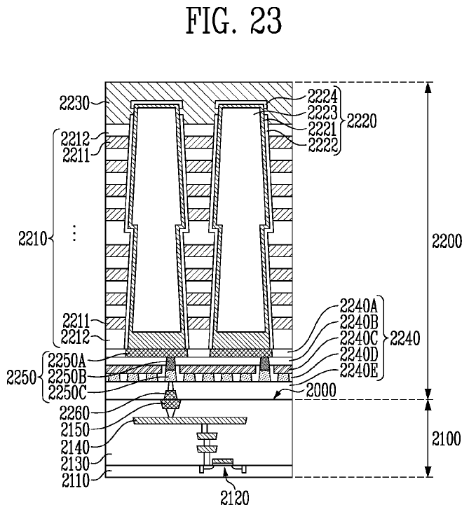

FIG. 23 is a diagram illustrating the structure of a semiconductor memory device according to an embodiment.

Referring to FIG. 23, the semiconductor memory device may include a first semiconductor structure 2100 and a second semiconductor structure 2200. A bonding interface 2000 may be located in the semiconductor memory device, and the first semiconductor structure 2100 may be distinguished from the second semiconductor structure 2200 by the bonding interface 2000. The second semiconductor structure 2200 may be disposed over or under the first semiconductor structure 2100. The first semiconductor structure 2100 may include a peripheral circuit structure, and the second semiconductor structure 2200 may include a memory cell array.

The first semiconductor structure 2100 may include a substrate 2110, a transistor 2120, a first insulator 2130, a first interconnection structure 2140, and a first conductive bonding pad 2150. The transistor 2120 may be included in the peripheral circuit structure. The peripheral circuit structure may include a row decoder, a page buffer, an input/output circuit, a logic circuit, and the like. The first interconnection structure 2140 may be disposed in the first insulator 2130 and may include a via, a wiring line, and the like. The first conductive bonding pad 2150 may be disposed at the bonding interface 2000 and may be electrically connected to the peripheral circuit structure through the first interconnection structure 2140.

The second semiconductor structure 2200 may include a gate stacked structure 2210, a cell pillar 2220, a source structure 2230, a second insulator 2240, a second interconnection structure 2250, and a second conductive bonding pad 2260. The gate stacked structure 2210 may include gate lines 2211 alternately stacked with insulating layers 2212. The gate lines 2211 correspond to the conductive layers described above with reference to FIGS. 6A to 6C. The insulating layers 2212 correspond to the interlayer insulating layers described above with reference to FIGS. 6A to 6C. The source structure 2230 may be disposed over the gate stacked structure 2210. The source structure 2230 may comprise the doped semiconductor structure described above with reference FIG. 10B. The cell pillar 2220 may be formed in a channel hole extending through the gate stacked structure 2210. The cell pillar 1220 may include channel structures spaced apart from each other in the same channel hole, as described above with reference to FIG. 4. The cell pillar 2220 may include a channel structure 2221, a memory layer 2222, a core insulating layer 2223, and/or a lower memory layer 2224. The channel structure 2221 may extend through the gate stacked structure 2210 and may be connected to the source structure 2230. The second interconnection structure 2250 may be disposed in the second insulator 2240. The second insulator 2240 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 2240 may include an interposing insulating layer 2240A, a first insulating layer 2240B, an etch stop layer 2240C, and a second insulating layer 2240D corresponding to the configuration of FIGS. 6A to 6C. Furthermore, the second insulator 2240 may further include a third insulating layer 2240E positioned between the second insulating layer 2240D and the first semiconductor structure 2100. The second interconnection structure 2250 may include a via, a wiring line, and the like. For example, the second interconnection structure 2250 may include a channel contact 2250A, a bit line contact 2250B, and a bit line 2250C, as configured in FIGS. 6A to 6C or FIGS. 9A to 9C. The second conductive bonding pad 2260 may be disposed at the bonding interface 2000 and may be electrically connected to the memory cell array through the second interconnection structure 2250.

The first conductive bonding pad 2150 may be electrically connected to the second conductive bonding pad 2260 at the bonding interface 2000, and the memory cell array may be electrically connected to the peripheral circuit structure through the first conductive bonding pad 2150 and the second conductive bonding pad 2260.

The semiconductor memory device may be manufactured using a method such as hybrid bonding, metal bonding, insulator bonding, or semiconductor bonding. For example, the semiconductor memory device may be manufactured by manufacturing a first wafer including the peripheral circuit structure and a second wafer including the memory cell array, and bonding the first wafer to the second wafer.

When the second wafer is manufactured, the source structure 2230 may be connected to the channel structure 2221 using a source sacrificial layer. For example, the cell pillar 2220 may be formed to protrude into a source structure including the source sacrificial layer. An opening exposing the cell pillar 2220 may be formed by removing the source sacrificial layer, and the channel structure 2221 may be exposed by etching the memory layer 2222 through the opening. A source layer connected to the channel structure 2221 may be formed in the opening to form the source structure 2230 including the source layer. The second wafer including the source structure 2230 may be flipped and bonded to the first wafer including the transistor 2120.

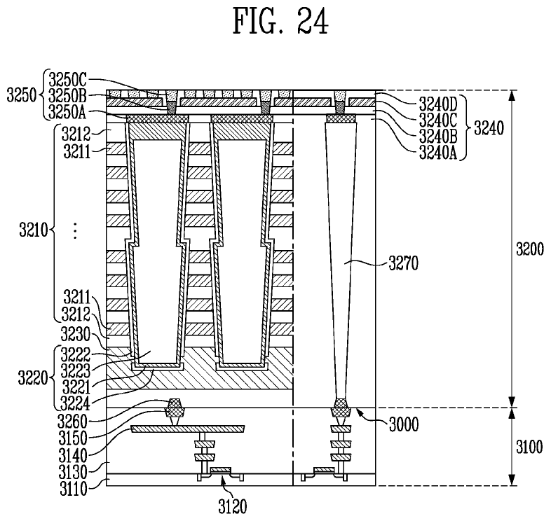

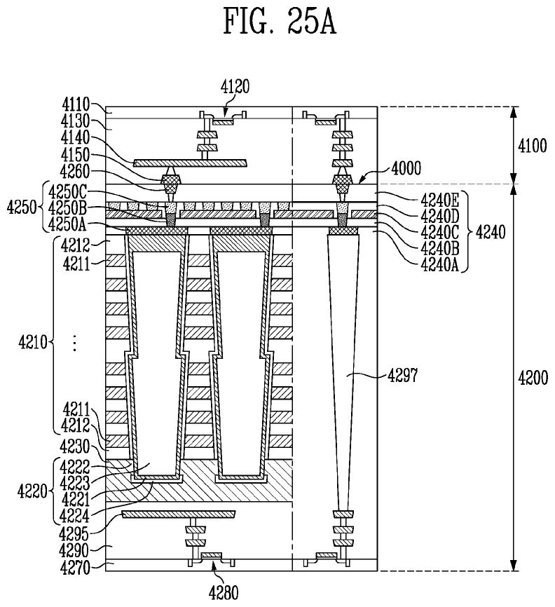

FIG. 24 is a diagram illustrating the structure of a semiconductor memory device according to an embodiment.

Referring to FIG. 24, the semiconductor memory device may include a first semiconductor structure 3100 and a second semiconductor structure 3200. A bonding interface 3000 may be located in the semiconductor memory device, and the first semiconductor structure 3100 may be distinguished from the second semiconductor structure 3200 by the bonding interface 3000. The second semiconductor structure 3200 may be disposed over or under the first semiconductor structure 3100. The first semiconductor structure 3100 may include a peripheral circuit structure, and the second semiconductor structure 3200 may include a memory cell array.

The first semiconductor structure 3100 may include a substrate 3110, a transistor 3120, a first insulator 3130, a first interconnection structure 3140, and a first conductive bonding pad 3150. The transistor 3120 may be included in the peripheral circuit structure. The peripheral circuit structure may include a row decoder, a page buffer, an input/output circuit, a logic circuit, and the like. The first interconnection structure 3140 may be disposed in the first insulator 3130 and may include a via, a wiring line, and the like. The first conductive bonding pad 3150 may be disposed at the bonding interface 3000 and may be electrically connected to the peripheral circuit structure through the first interconnection structure 3140.

The second semiconductor structure 3200 may include a gate stacked structure 3210, a cell pillar 3220, a source structure 3230, a second insulator 3240, a second interconnection structure 3250, a second conductive bonding pad 3260, and a contact plug 3270. The gate stacked structure 3210 may include gate lines 3211 alternately stacked with insulating layers 3212. The gate lines 3211 correspond to the conductive layers described above with reference to FIGS. 6A to 6C. The insulating layers 3212 correspond to the interlayer insulating layers described above with reference to FIGS. 6A to 6C. The source structure 3230 may be disposed below the gate stacked structure 3210. The source structure 3230 may comprise the doped semiconductor structure described above with reference FIG. 10B. The cell pillar 3220 may be formed in a channel hole extending through the gate stacked structure 3210. The cell pillar 3220 may include channel structures spaced apart from each other in the same channel hole, as described above with reference to FIG. 4. The cell pillar 3220 may include a channel structure 3221, a memory layer 3222, a core insulating layer 3223, and/or a lower memory layer 3224. The channel structure 3221 may extend through the gate stacked structure 3210, and may be connected to the source structure 3230. The second interconnection structure 3250 may be disposed in the second insulator 3240. The second insulator 3240 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 3240 may include an interposing insulating layer 3240A, a first insulating layer 3240B, an etch stop layer 3240C, and a second insulating layer 3240D corresponding to the configuration of FIGS. 6A to 6C. The second interconnection structure 3250 may include a via, a wiring line, and the like. For example, the second interconnection structure 3250 may include a channel contact 3250A, a bit line contact 3250B, and a bit line 3250C, as configured in FIGS. 6A to 6C or FIGS. 9A to 9C. The second conductive bonding pad 3260 may be disposed at the bonding interface 3000 and may be electrically connected to the memory cell array through the second interconnection structure 3250.

The first conductive bonding pad 3150 may be electrically connected to the second conductive bonding pad 3260 at the bonding interface 3000, and the memory cell array may be electrically connected to the peripheral circuit structure through the first conductive bonding pad 3150 and the second conductive bonding pad 3260. The contact plug 3270 may extend through the second insulator 3240 or a dummy stack and may be connected to the peripheral circuit structure through the first conductive bonding pad 3150 and the second conductive bonding pad 3260.

The semiconductor memory device may be manufactured using a method such as hybrid bonding, metal bonding, insulator bonding, or semiconductor bonding. For example, the semiconductor memory device may be manufactured by manufacturing a first wafer including the peripheral circuit structure and a second wafer including the memory cell array, and bonding the first wafer to the second wafer.

When the second wafer is manufactured, the source structure 3230 may be connected to the channel structure 3221 using a source sacrificial layer. For example, the cell pillar 3220 protrudes into a source structure including the source sacrificial layer. Subsequently, an opening exposing the cell pillar 3220 may be formed by removing the source sacrificial layer, and the channel structure 3221 may be exposed by etching the memory layer 3222 through the opening. A source layer connected to the channel structure 3221 may be formed in the opening to form the source structure 3230 including the source layer. The second wafer including the source structure 3230 may be bonded to the first wafer including the transistor 3120. In this example, the second wafer may be bonded to the first wafer in an un-flipped state. An interconnection structure such as a through silicon via (TSV) may be formed.

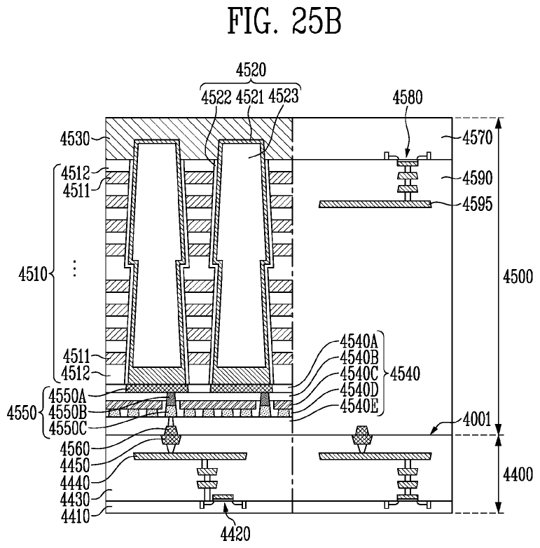

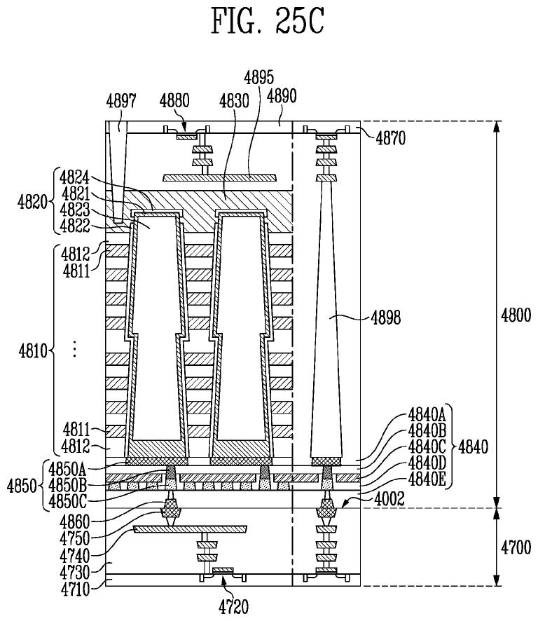

FIG. 25A is a diagram illustrating the structure of a semiconductor memory device according to an embodiment.

Referring to FIG. 25A, the semiconductor memory device may include a first semiconductor structure 4100 and a second semiconductor structure 4200. A bonding interface 4000 may be located in the semiconductor memory device, and the first semiconductor structure 4100 may be distinguished from the second semiconductor structure 4200 by the bonding interface 4000. The second semiconductor structure 4200 may be disposed over or under the first semiconductor structure 4100. A peripheral circuit structure may include a first peripheral circuit structure and a second peripheral circuit structure. The first peripheral circuit structure and the second peripheral circuit structure may be distributed and disposed in the first semiconductor structure 4100 and the second semiconductor structure 4200. The first semiconductor structure 4100 may include the first peripheral circuit structure, and the second semiconductor structure 4200 may include the second peripheral circuit structure and a memory cell array.

The first semiconductor structure 4100 may include a first substrate 4110, a first transistor 4120, a first insulator 4130, a first interconnection structure 4140, and a first conductive bonding pad 4150. The first transistor 4120 may be included in the first peripheral circuit structure. The first peripheral circuit structure may include a row decoder, a page buffer, an input/output circuit, a logic circuit, and the like. The first interconnection structure 4140 may be disposed in the first insulator 4130 and may include a via, a wiring line, and the like. The first conductive bonding pad 4150 may be disposed at the bonding interface 4000 and may be electrically connected to the first peripheral circuit structure through the first interconnection structure 4140.

The second semiconductor structure 4200 may include a gate stacked structure 4210, a cell pillar 4220, a source structure 4230, a second insulator 4240, a second interconnection structure 4250, a second conductive bonding pad 4260, a second substrate 4270, a second transistor 4280, a third insulator 4290, a third interconnection structure 4295, and a contact plug 4297.

The second transistor 4280 may be disposed on the second substrate 4270. The second transistor 4280 may be included in the second peripheral circuit structure. The second peripheral circuit structure may include a row decoder, a page buffer, an input/output circuit, a logic circuit, and the like. The third interconnection structure 4295 may be formed in the third insulator 4290 and may include a via, a wiring line, and the like. The third interconnection structure 4295 may be electrically connected to the second peripheral circuit structure.

The gate stacked structure 4210 may be disposed over the second peripheral circuit. The gate stacked structure 4210 may include gate lines 4211 alternately stacked with insulating layers 4212. The gate lines 4211 correspond to the conductive layers described above with reference to FIGS. 6A to 6C. The insulating layers 4212 correspond to the interlayer insulating layers described above with reference to FIGS. 6A to 6C. The source structure 4230 may be disposed under the gate stacked structure 4210. The source structure 4230 may comprise the doped semiconductor structure described above with reference FIG. 10B. The cell pillar 4220 may be formed in a channel hole extending through the gate stacked structure 4210. The cell pillar 4220 may include channel structures spaced apart from each other in the same channel hole, as described above with reference to FIG. 4. The cell pillar 4220 may include a channel structure 4221, a memory layer 4222, a core insulating layer 4223, and/or a lower memory layer 4224. The channel structure 4221 may extend through the gate stacked structure 4210 and may be connected to the source structure 4230. The second interconnection structure 4250 may be disposed in the second insulator 4240. The second insulator 4240 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 4240 may include an interposing insulating layer 4240A, a first insulating layer 4240B, an etch stop layer 4240C, and a second insulating layer 4240D corresponding to the configuration of FIGS. 6A to 6C. Furthermore, the second insulator 4240 may further include a third insulating layer 4240E positioned between the second insulating layer 4240D and the first semiconductor structure 4100. The second interconnection structure 4250 may include a via, a wiring line, and the like. For example, the second interconnection structure 4250 may include a channel contact 4250A, a bit line contact 4250B, and a bit line 4250C, as configured in FIGS. 6A to 6C or FIGS. 9A to 9C. The second conductive bonding pad 4260 may be disposed at the bonding interface 4000 and may be electrically connected to the memory cell array through the second interconnection structure 4250.

The first conductive bonding pad 4150 may be electrically connected to the second conductive bonding pad 4260 at the bonding interface 4000, and the memory cell array may be electrically connected to the first peripheral circuit structure through the first conductive bonding pad 4150 and the second conductive bonding pad 4260. The contact plug 4297 may extend through the second insulator 4240 or a dummy stack. The first peripheral circuit structure may be connected to the second peripheral circuit structure through the contact plug 4297, the first conductive bonding pad 4150 and the second conductive bonding pad 4260.

The semiconductor memory device may be manufactured using a method such as hybrid bonding, metal bonding, insulator bonding, or semiconductor bonding. For example, the semiconductor memory device may be manufactured by manufacturing a first wafer including the first peripheral circuit structure and a second wafer including the second peripheral circuit structure and the memory cell array, and bonding the first wafer to the second wafer.

When the second wafer is manufactured, the source structure 4230 may be connected to the channel structure 4221 using a source sacrificial layer. For example, the second peripheral circuit structure may be formed on the second substrate 4270, and a source structure including the source sacrificial layer and the cell pillar 4220 protruding into the source structure may be formed over the second peripheral circuit structure. An opening exposing the cell pillar 4220 may be formed by removing the source sacrificial layer, and the channel structure 4221 may be exposed by etching the memory layer 4222 through the opening. A source layer connected to the channel structure 4221 may be formed in the opening to form the source structure 4230 including the source layer. The second wafer including the second peripheral circuit structure and the source structure 4230 may be bonded to the first wafer including the first peripheral circuit structure.

FIG. 25B is a diagram illustrating the structure of a semiconductor memory device according to an embodiment.

Referring to FIG. 25B, the semiconductor memory device may include a first semiconductor structure 4400 and a second semiconductor structure 4500. A bonding interface 4001 may be located in the semiconductor memory device, and the first semiconductor structure 4400 may be distinguished from the second semiconductor structure 4500 by the bonding interface 4001. The second semiconductor structure 4500 may be disposed over or under the first semiconductor structure 4400. A peripheral circuit structure may include a first peripheral circuit structure and a second peripheral circuit structure. The first peripheral circuit structure and the second peripheral circuit structure may be distributed and disposed in the first semiconductor structure 4400 and the second semiconductor structure 4500. The first semiconductor structure 4400 may include the first peripheral circuit structure, and the second semiconductor structure 4500 may include the second peripheral circuit structure and a memory cell array.

The first semiconductor structure 4400 may include a first substrate 4410, a first transistor 4420, a first insulator 4430, a first interconnection structure 4440, and a first conductive bonding pad 4450. The first transistor 4420 may be included in the first peripheral circuit structure. The first peripheral circuit structure may include a row decoder, a page buffer, an input/output circuit, a logic circuit, and the like. The first interconnection structure 4440 may be disposed in the first insulator 4430 and may include a via, a wiring line, and the like. The first interconnection structure 4440 may be electrically connected to the first peripheral circuit structure.

The second semiconductor structure 4500 may include a gate stacked structure 4510, a cell pillar 4520, a source structure 4530, a second insulator 4540, a second interconnection structure 4550, a second conductive bonding pad 4560, a second substrate 4570, a second transistor 4580, a third insulator 4590, and a third interconnection structure 4595.

The second transistor 4580 may be disposed on the second substrate 4570. The second transistor 4580 may be included in the second peripheral circuit structure. The third interconnection structure 4595 may be formed in the third insulator 4590 and may include a via, a wiring line, and the like. The third interconnection structure 4595 may be electrically connected to the second peripheral circuit structure.

The source structure 4530 may be disposed at a level corresponding to the second substrate 4570, and the gate stacked structure 4510 may be disposed under the source structure 4530. The source structure 4530 may comprise the doped semiconductor structure described above with reference FIG. 10A. The gate stacked structure 4510 may include gate lines 4511 alternately stacked with insulating layers 4512. The gate lines 4511 correspond to the conductive layers described above with reference to FIGS. 6A to 6C. The insulating layers 4512 correspond to the interlayer insulating layers described above with reference to FIGS. 6A to 6C. The cell pillar 4520 may be formed in a channel hole extending through the gate stacked structure 4510. The cell pillar 4520 may include channel structures spaced apart from each other in the same channel hole, as described above with reference to FIG. 4. The cell pillar 4520 may include a channel structure 4521, a memory layer 4522, and/or a core insulating layer 4523. The channel structure 4521 may extend through the gate stacked structure 4510 and may be connected to the source structure 4530. The second interconnection structure 4550 may be disposed in the second insulator 4540. The second insulator 4540 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 4540 may include an interposing insulating layer 4540A, a first insulating layer 4540B, an etch stop layer 4540C, and a second insulating layer 4540D corresponding to the configuration of FIGS. 6A to 6C. Furthermore, the second insulator 4540 may further include a third insulating layer 4540E positioned between the second insulating layer 4540D and the first semiconductor structure 4400. The second interconnection structure 4550 may include a via, a wiring line, and the like. For example, the second interconnection structure 4550 may include a channel contact 4550A, a bit line contact 4550B, and a bit line 4550C, as configured in FIGS. 6A to 6C or FIGS. 9A to 9C. The second conductive bonding pad 4560 may be disposed at the bonding interface 4001, and may be electrically connected to the memory cell array through the second interconnection structure 4550.

The first conductive bonding pad 4450 may be electrically connected to the second conductive bonding pad 4560 at the bonding interface 4001, and the memory cell array may be electrically connected to the first peripheral circuit structure through the first conductive bonding pad 4450 and the second conductive bonding pad 4560.

The semiconductor memory device may be manufactured using a method such as hybrid bonding, metal bonding, insulator bonding, or semiconductor bonding. For example, the semiconductor memory device may be manufactured by manufacturing a first wafer including the first peripheral circuit structure and a second wafer including the second peripheral circuit structure and the memory cell array, and bonding the first wafer to the second wafer.

Some of the first semiconductor structure 4400 and the second semiconductor structure 4500 may be formed after the first wafer is bonded to the second wafer. For example, the second peripheral circuit structure may be formed in a peripheral region of the second substrate 4560, and the cell pillar 4520 protruding into the second substrate 4570 may be formed in a cell region of the second substrate 4570. The second wafer including the second peripheral circuit structure and the source structure 4530 may be flipped and bonded to the first wafer including the first peripheral circuit structure. Subsequently, a rear surface of the gate stacked structure 4510 may be exposed by removing the cell region of the second substrate 4570, and the channel structure 4521 may be exposed by etching the memory layer 4522 of the cell pillar 4520 protruding from the rear surface of the gate stacked structure 4510. The source structure 4530 may be formed on the rear surface of the gate stacked structure 4510.

FIG. 25C is a diagram illustrating the structure of a semiconductor memory device according to an embodiment.

Referring to FIG. 25C, the semiconductor memory device may include a first semiconductor structure 4700 and a second semiconductor structure 4800. A bonding interface 4002 may be located in the semiconductor memory device, and the first semiconductor structure 4700 may be distinguished from the second semiconductor structure 4800 by the bonding interface 4002. The second semiconductor structure 4800 may be disposed over or under the first semiconductor structure 4700. A peripheral circuit structure may include a first peripheral circuit structure and a second peripheral circuit structure. The first peripheral circuit structure and the second peripheral circuit structure may be distributed and disposed in the first semiconductor structure 4700 and the second semiconductor structure 4800. The first semiconductor structure 4700 may include the first peripheral circuit structure, and the second semiconductor structure 4800 may include the second peripheral circuit structure and a memory cell array.

The first semiconductor structure 4700 may include a first substrate 4710, a first transistor 4720, a first insulator 4730, a first interconnection structure 4740, and a first conductive bonding pad 4750. The first transistor 4720 may be included in the first peripheral circuit structure. The first peripheral circuit structure may include a row decoder, a page buffer, an input/output circuit, a logic circuit, and the like. The first interconnection structure 4740 may be disposed in the first insulator 4730 and may include a via, a wiring line, and the like. The first conductive bonding pad 4750 may be disposed at the bonding interface 4002 and may be electrically connected to the first peripheral circuit structure through the first interconnection structure 4740.

The second semiconductor structure 4800 may include a gate stacked structure 4810, a cell pillar 4820, a source structure 4830, a second insulator 4840, a second interconnection structure 4850, a second conductive bonding pad 4860, a second substrate 4870, a second transistor 4880, a third insulator 4890, a third interconnection structure 4895, a through via 4897, and a contact plug 4898.

The second transistor 4880 may be disposed on the second substrate 4870. The second transistor 4880 may be included in the second peripheral circuit structure. The second peripheral circuit structure may include a row decoder, a page buffer, an input/output circuit, a logic circuit, and the like. The third interconnection structure 4895 may be formed in the third insulator 4890 and may include a via, a wiring line, and the like. The third interconnection structure 4895 may be electrically connected to the second peripheral circuit structure.

The source structure 4830 may be disposed under the second peripheral circuit structure. The source structure 4830 may comprise the doped semiconductor structure described above with reference FIG. 10B. The through via 4897 may extend through the second substrate 4870 and the third insulator 4890 and may be connected to the source structure 4830. The gate stacked structure 4810 may be disposed under the source structure 4830. The gate stacked structure 4810 may include gate lines 4811 alternately stacked with insulating layers 4812. The gate lines 4811 correspond to the conductive layers described above with reference to FIGS. 6A to 6C. The insulating layers 4812 correspond to the interlayer insulating layers described above with reference to FIGS. 6A to 6C. The cell pillar 4820 may be formed in a channel hole extending through the gate stacked structure 4810. The cell pillar 4820 may include channel structures spaced apart from each other in the same channel hole, as described above with reference to FIG. 4. The cell pillar 4820 may include a channel structure 4821, a memory layer 4822, a core insulating layer 4823, and/or a lower memory layer 4824. The channel structure 4821 may extend through the gate stacked structure 4810 and may be connected to the source structure 4830. The second interconnection structure 4850 may be disposed in the second insulator 4840. The second insulator 4840 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 4840 may include an interposing insulating layer 4840A, a first insulating layer 4840B, an etch stop layer 4840C, and a second insulating layer 4840D corresponding to the configuration of FIGS. 6A to 6C. Furthermore, the second insulator 4840 may further include a third insulating layer 4840E positioned between the second insulating layer 4840D and the first semiconductor structure 4700. The second interconnection structure 4850 may include a via, a wiring line, and the like. For example, the second interconnection structure 4850 may include a channel contact 4850A, a bit line contact 4850B, and a bit line 4850C, as configured in FIGS. 6A to 6C or FIGS. 9A to 9C. The second conductive bonding pad 4860 may be disposed at the bonding interface 4002 and may be electrically connected to the memory cell array through the second interconnection structure 4850.

The first conductive bonding pad 4750 may be electrically connected to the second conductive bonding pad 4860 at the bonding interface 4002, and the memory cell array may be electrically connected to the first peripheral circuit structure through the first conductive bonding pad 4750 and the second conductive bonding pad 4860. The contact plug 4898 may extend through the second insulator 4840 or a dummy stack. The first peripheral circuit structure may be connected to the second peripheral circuit structure through the contact plug 4898, the first conductive bonding pad 4750 and the second conductive bonding pad 4860.

The semiconductor memory device may be manufactured using a method such as hybrid bonding, metal bonding, insulator bonding, or semiconductor bonding. For example, the semiconductor memory device may be manufactured by manufacturing a first wafer including the first peripheral circuit structure and a second wafer including the second peripheral circuit structure and the memory cell array, and bonding the first wafer to the second wafer.

Some of the first semiconductor structure 4700 and the second semiconductor structure 4800 may be formed after the first wafer may be bonded to the second wafer. For example, the second wafer including the second substrate 4870, the second peripheral circuit structure, and a source structure including a source sacrificial layer may be formed. The second wafer may be flipped and bonded to the first wafer including the first peripheral circuit structure. Subsequently, a through hole extending through the second substrate 4870 and the third insulator 4890 to expose the source sacrificial layer may be formed, and an opening, through which the cell pillar 4820 is exposed, may be formed by removing the source sacrificial layer through the through hole. The channel structure 4821 may be exposed by etching the memory layer 4822 through the opening, and a source layer connected to the channel structure 4821 may be formed in the opening to form the source structure 4830 including the source layer. The through via 4897 may be formed in the through hole.

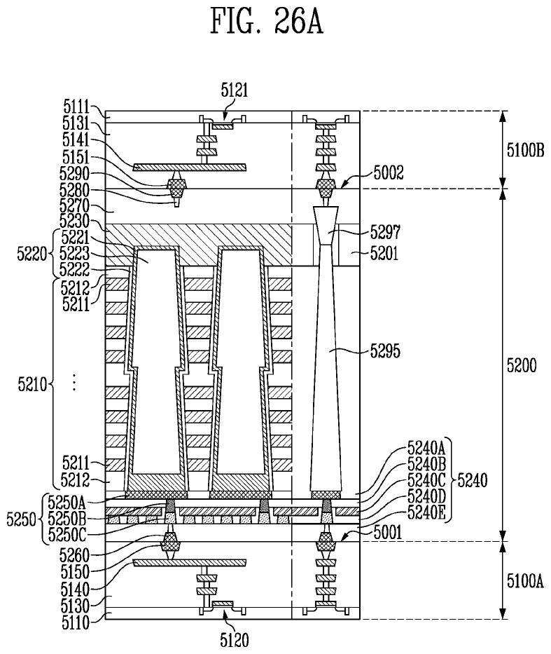

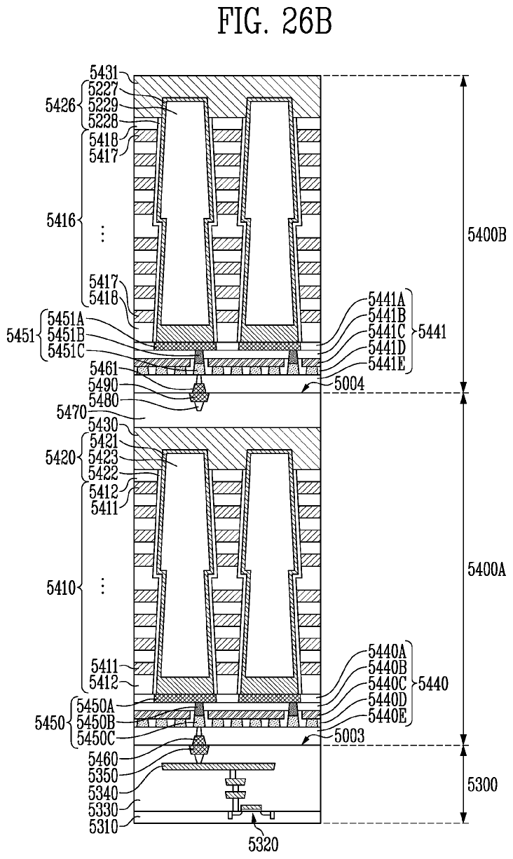

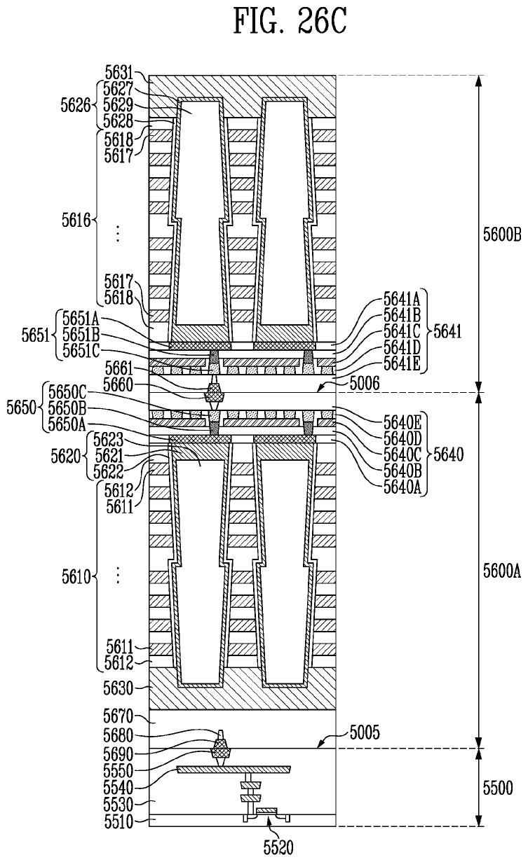

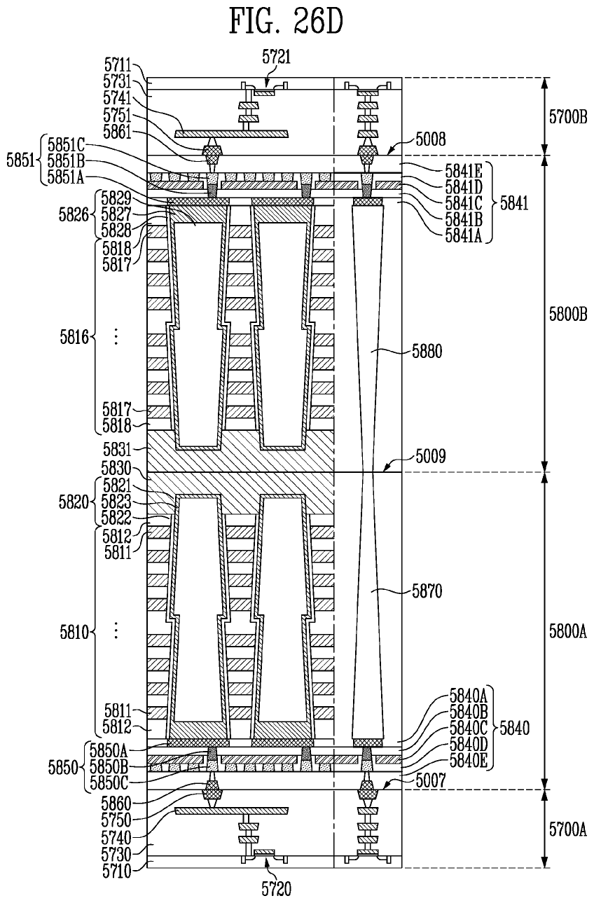

FIG. 26A is a diagram illustrating the structure of a semiconductor memory device according to an embodiment.

Referring to FIG. 26A, the semiconductor memory device may include a first semiconductor structure 5100A, a second semiconductor structure 5100B, and a third semiconductor structure 5200. Bonding interfaces 5001 and 5002 may be located in the semiconductor memory device, and the first semiconductor structure 5100A, the second semiconductor structure 5100B, and the third semiconductor structure 5200 may be distinguished from each other by the bonding interfaces 5001 and 5002. The third semiconductor structure 5200 may be disposed between the first semiconductor structure 5100A and the second semiconductor structure 5100B. A peripheral circuit structure may include a first peripheral circuit structure and a second peripheral circuit structure. The first peripheral circuit structure and the second peripheral circuit structure may be distributed and disposed in the first semiconductor structure 5100A and the second semiconductor structure 5100B. The first semiconductor structure 5100A may include the first peripheral circuit structure, the second semiconductor structure 5100B may include the second peripheral circuit structure, and the third semiconductor structure 5200 may include a memory cell array.

The first semiconductor structure 5100A may include a first substrate 5110, a first transistor 5120, a first insulator 5130, a first interconnection structure 5140, and a first conductive bonding pad 5150. The first transistor 5120 may be included in the first peripheral circuit structure. The first peripheral circuit structure may include a row decoder, a page buffer, an input/output circuit, a logic circuit, and the like. The first interconnection structure 5140 may be disposed in the first insulator 5130 and may include a via, a wiring line, and the like. The first conductive bonding pad 5150 may be disposed at a first bonding interface 5001 and may be electrically connected to the first peripheral circuit structure through the first interconnection structure 5140.

The second semiconductor structure 5100B may include a second substrate 5111, a second transistor 5121, a second insulator 5131, a second interconnection structure 5141, and a second conductive bonding pad 5151. The second transistor 5121 may be included in the second peripheral circuit structure. The second peripheral circuit structure may include a row decoder, a page buffer, an input/output circuit, a logic circuit, and the like. The second interconnection structure 5141 may be disposed in the second insulator 5131 and may include a via, a wiring line, and the like. The second conductive bonding pad 5151 may be disposed at a second bonding interface 5002 and may be electrically connected to the second peripheral circuit structure through the second interconnection structure 5141.

The third semiconductor structure 5200 may include a substrate 5201, a gate stacked structure 5210, a cell pillar 5220, a source structure 5230, a third insulator 5240, a third interconnection structure 5250, a third conductive bonding pad 5260, a fourth insulator 5270, a fourth interconnection structure 5280, a fourth conductive bonding pad 5290, a first contact plug 5295, and a second contact plug 5297. The gate stacked structure 5210 may include gate lines 5211 alternately stacked with insulating layers 5212. The gate lines 5211 correspond to the conductive layers described above with reference to FIGS. 6A to 6C. The insulating layers 5212 correspond to the interlayer insulating layers described above with reference to FIGS. 6A to 6C. The source structure 5230 may be disposed over or under the gate stacked structure 5210. The source structure 5230 may comprise the doped semiconductor structure described above with reference FIG. 10A. The cell pillar 5220 may be formed in a channel hole extending through the gate stacked structure 5210. The cell pillar 5220 may include channel structures spaced apart from each other in the same channel hole, as described above with reference to FIG. 4. The cell pillar 5220 may include a channel structure 5221, a memory layer 5222, and/or a core insulating layer 5223. The channel structure 5221 may extend through the gate stacked structure 5210 and may be connected to the source structure 5230. The third interconnection structure 5250 may be disposed in the third insulator 5240. The third insulator 5240 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the third insulator 5240 may include an interposing insulating layer 5240A, a first insulating layer 5240B, an etch stop layer 5240C, and a second insulating layer 5240D corresponding to the configuration of FIGS. 6A to 6C. Furthermore, the third insulator 5240 may further include a third insulating layer 5240E positioned between the second insulating layer 5240D and the first semiconductor structure 5100A. The third interconnection structure 5250 may include a via, a wiring line, and the like. For example, the third interconnection structure 5250 may include a channel contact 5250A, a bit line contact 5250B, and a bit line 5250C, as configured in FIGS. 6A to 6C or FIGS. 9A to 9C. The fourth interconnection structure 5280 may be disposed in the fourth insulator 5270 and may include a via, a wiring line, and the like. The third conductive bonding pad 5260 may be disposed at the first bonding interface 5001 and may be electrically connected to the memory cell array through the third interconnection structure 5250. The fourth conductive bonding pad 5290 may be disposed at the second bonding interface 5002 and may be electrically connected to the memory cell array through the fourth interconnection structure 5280.

The first conductive bonding pad 5150 may be electrically connected to the third conductive bonding pad 5260 at the first bonding interface 5001, and the memory cell array may be electrically connected to the first peripheral circuit structure through the first conductive bonding pad 5150 and the third conductive bonding pad 5260. The second conductive bonding pad 5151 may be electrically connected to the fourth conductive bonding pad 5290 at the second bonding interface 5002, and the memory cell array may be electrically connected to the second peripheral circuit structure through the second conductive bonding pad 5151 and the fourth conductive bonding pad 5290.

The first contact plug 5295 may extend through the third insulator 5240 or a dummy stack, and the second contact plug 5297 may extend through the third substrate 5201. The first contact plug 5295 may be connected to the second contact plug 5297, and the first peripheral circuit structure may be connected to the second peripheral circuit structure through the first conductive bonding pad 5150, the third conductive bonding pad 5260, the first contact plug 5295, the second contact plug 5297, the fourth conductive bonding pad 5290, and the second conductive bonding pad 5151.

The semiconductor memory device may be manufactured using a method such as hybrid bonding, metal bonding, insulator bonding, or semiconductor bonding. The semiconductor memory device may be manufactured by manufacturing a first wafer including the first peripheral circuit structure, a second wafer including the second peripheral circuit structure, and a third wafer including the memory cell array, and bonding the first to third wafers together. For example, the third wafer may be flipped and bonded to the first wafer, and a substrate of the third wafer may be removed to form the source structure 5230. The second wafer may be flipped and bonded to the third wafer.

FIG. 26B is a diagram illustrating the structure of a semiconductor memory device according to an embodiment.

Referring to FIG. 26B, the semiconductor memory device may include a first semiconductor structure 5300, a second semiconductor structure 5400A, and a third semiconductor structure 5400B. Bonding interfaces 5003 and 5004 may be located in the semiconductor memory device, and the first semiconductor structure 5300, the second semiconductor structure 5400A, and the third semiconductor structure 5400B may be distinguished by the bonding interfaces 5003 and 5004. The second semiconductor structure 5400A may be disposed between the first semiconductor structure 5300 and the third semiconductor structure 5400B. The first semiconductor structure 5300 may include a peripheral circuit structure, the second semiconductor structure 5400A may include a first memory cell array, and the third semiconductor structure 5400B may include a second memory cell array.

The first semiconductor structure 5300 may include a substrate 5310, a transistor 5320, a first insulator 5330, a first interconnection structure 5340, and a first conductive bonding pad 5350. The transistor 5320 may be included in the peripheral circuit structure. The peripheral circuit structure may include a row decoder, a page buffer, an input/output circuit, a logic circuit, and the like. The first interconnection structure 5340 may be disposed in the first insulator 5330 and may include a via, a wiring line, and the like. The first conductive bonding pad 5350 may be disposed at a first bonding interface 5003 and may be electrically connected to the peripheral circuit structure through the first interconnection structure 5340.

The second semiconductor structure 5400A may include a first gate stacked structure 5410, a first cell pillar 5420, a first source structure 5430, a second insulator 5440, a second interconnection structure 5450, a second conductive bonding pad 5460, a third insulator 5470, a third interconnection structure 5480, and a third conductive bonding pad 5490. The first gate stacked structure 5410 may include first gate lines 5411 alternately stacked with first interlayer insulating layers 5412. The first gate lines 5411 correspond to the conductive layers described above with reference to FIGS. 6A to 6C. The first interlayer insulating layers 5412 correspond to the interlayer insulating layers described above with reference to FIGS. 6A to 6C. The first source structure 5430 may be disposed over or under the first gate stacked structure 5410. The first source structure 5430 may comprise the doped semiconductor structure described above with reference FIG. 10A. The first cell pillar 5420 may be formed in a channel hole extending through the first gate stacked structure 5410. The first cell pillar 5420 may include channel structures spaced apart from each other in the same channel hole, as described above with reference to FIG. 4. The first cell pillar 5420 may include a first channel structure 5421, a first memory layer 5422, and/or a first core insulating layer 5423. The first channel structure 5421 may extend through the first gate stacked structure 5410 and may be connected to the first source structure 5430. The second interconnection structure 5450 may be disposed in the second insulator 5440. The second insulator 5440 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 5440 may include an interposing insulating layer 5440A, a first insulating layer 5440B, an etch stop layer 5440C, and a second insulating layer 5440D corresponding to the configuration of FIGS. 6A to 6C. Furthermore, the second insulator 5440 may further include a third insulating layer 5440E positioned between the second insulating layer 5440D and the first semiconductor structure 5300. The second interconnection structure 5450 may include a via, a wiring line, and the like. For example, the second interconnection structure 5450 may include a channel contact 5450A, a bit line contact 5450B, and a bit line 5450C, as configured in FIGS. 6A to 6C or FIGS. 9A to 9C. The third interconnection structure 5480 may be disposed in the third insulator 5470 and may include a via, a wiring line, and the like. The second conductive bonding pad 5460 may be disposed at the first bonding interface 5003 and may be electrically connected to the first memory cell array through the second interconnection structure 5450. The third conductive bonding pad 5490 may be disposed at a second bonding interface 5004, and may be electrically connected to the first memory cell array through the third interconnection structure 5480.

The third semiconductor structure 5400B may include a second gate stacked structure 5416, a second cell pillar 5426, a second source structure 5431, a fourth insulator 5441, a fourth interconnection structure 5451, and a fourth conductive bonding pad 5461. The second gate stacked structure 5416 may include second gate lines 5417 alternately stacked with second interlayer insulating layers 5418. The second gate lines 5417 correspond to the conductive layers described above with reference to FIGS. 6A to 6C. The second interlayer insulating layers 5418 correspond to the interlayer insulating layers described above with reference to FIGS. 6A to 6C. The second source structure 5431 may be disposed over or under the second gate stacked structure 5416. The second source structure 5431 may comprise the doped semiconductor structure described above with reference FIG. 10A. The second source structure 5431 may be electrically isolated from the first source structure 5430 and driven separately from the first source structure 5430 or may be electrically connected to the first source structure 5430 and driven in common with the first source structure 5430. The second cell pillar 5426 may be formed in a channel hole extending through the second gate stacked structure 5416. The second cell pillar 5426 may include channel structures spaced apart from each other in the same channel hole, as described above with reference to FIG. 4. The second cell pillar 5426 may include a second channel structure 5427, a second memory layer 5428, and/or a second core insulating layer 5429. The second channel structure 5427 may extend through the second gate stacked structure 5416 and may be connected to the second source structure 5431. The fourth interconnection structure 5451 may be disposed in the fourth insulator 5441. The fourth insulator 5441 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the fourth insulator 5441 may include an interposing insulating layer 5441A, a first insulating layer 5441B, an etch stop layer 5441C, and a second insulating layer 5441D corresponding to the configuration of FIGS. 6A to 6C. Furthermore, the fourth insulator 5441 may further include a third insulating layer 5441E positioned between the second insulating layer 5441D and the second semiconductor structure 5400A. The fourth interconnection structure 5451 may include a via, a wiring line, and the like. For example, the fourth interconnection structure 5451 may include a channel contact 5451A, a bit line contact 5451B, and a bit line 5451C, as configured in FIGS. 6A to 6C or FIGS. 9A to 9C. The fourth conductive bonding pad 5461 may be disposed at the second bonding interface 5004 and may be electrically connected to the second memory cell array through the fourth interconnection structure 5451.

The first conductive bonding pad 5350 may be electrically connected to the second conductive bonding pad 5460 at the first bonding interface 5003, and the first memory cell array may be electrically connected to the peripheral circuit structure through the first conductive bonding pad 5350 and the second conductive bonding pad 5460. The third conductive bonding pad 5490 may be electrically connected to the fourth conductive bonding pad 5461 at the second bonding interface 5004, and the second memory cell array may be electrically connected to the first memory cell array through the third conductive bonding pad 5490 and the fourth conductive bonding pad 5461.

The semiconductor memory device may be manufactured using a method such as hybrid bonding, metal bonding, insulator bonding, or semiconductor bonding. The semiconductor memory device may be manufactured by manufacturing a first wafer including the peripheral circuit structure, a second wafer including the first memory cell array, and a third wafer including the second memory cell array, and bonding the first to third wafers together. For example, the second wafer may be flipped and bonded to the first wafer, and a substrate of the second wafer may be removed to form the first source structure 5430. The third wafer may be flipped and bonded to the second wafer, and a substrate of the third wafer may be removed to form the second source structure 5431.

FIG. 26C is a diagram illustrating the structure of a semiconductor memory device according to an embodiment.

Referring to FIG. 26C, the semiconductor memory device may include a first semiconductor structure 5500, a second semiconductor structure 5600A, and a third semiconductor structure 5600B. Bonding interfaces 5005 and 5006 may be located in the semiconductor memory device, and the first semiconductor structure 5500, the second semiconductor structure 5600A, and the third semiconductor structure 5600B may be distinguished by the bonding interfaces 5005 and 5006. The second semiconductor structure 5600A may be disposed between the first semiconductor structure 5500 and the third semiconductor structure 5600B. The first semiconductor structure 5500 may include a peripheral circuit structure, the second semiconductor structure 5600A may include a first memory cell array, and the third semiconductor structure 5600B may include a second memory cell array.

The first semiconductor structure 5500 may include a substrate 5510, a transistor 5520, a first insulator 5530, a first interconnection structure 5540, and a first conductive bonding pad 5550. The transistor 5520 may be included in the peripheral circuit structure. The peripheral circuit structure may include a row decoder, a page buffer, an input/output circuit, a logic circuit, and the like. The first interconnection structure 5540 may be disposed in the first insulator 5530 and may include a via, a wiring line, and the like. The first conductive bonding pad 5550 may be disposed at a first bonding interface 5005 and may be electrically connected to the peripheral circuit structure through the first interconnection structure 5540.

The second semiconductor structure 5600A may include a first gate stacked structure 5610, a first cell pillar 5620, a first source structure 5630, a second insulator 5640, a second interconnection structure 5650, a second conductive bonding pad 5660, a third insulator 5670, a third interconnection structure 5680, and a third conductive bonding pad 5690. The first gate stacked structure 5610 may include first gate lines 5611 alternately stacked with first interlayer insulating layers 5612. The first gate lines 5611 correspond to the conductive layers described above with reference to FIGS. 6A to 6C. The first interlayer insulating layers 5612 correspond to the interlayer insulating layers described above with reference to FIGS. 6A to 6C. The first source structure 5630 may be disposed over or under the first gate stacked structure 5610. The first source structure 5630 may comprise the doped semiconductor structure described above with reference FIG. 10A. The first cell pillar 5620 may be formed in a channel hole extending through the first gate stacked structure 5610. The first cell pillar 5620 may include channel structures spaced apart from each other in the same channel hole, as described above with reference to FIG. 4. The first cell pillar 5620 may include a first channel structure 5621, a first memory layer 5622, and/or a first core insulating layer 5623. The first channel structure 5621 may extend through the first gate stacked structure 5610 and may be connected to the first source structure 5630. The second interconnection structure 5650 may be disposed in the second insulator 5640. The second insulator 5640 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the second insulator 5640 may include an interposing insulating layer 5640A, a first insulating layer 5640B, an etch stop layer 5640C, and a second insulating layer 5640D corresponding to the configuration of FIGS. 6A to 6C. Furthermore, the second insulator 5640 may further include a third insulating layer 5640E positioned between the second insulating layer 5640D and the third semiconductor structure 5600B. The second interconnection structure 5650 may include a via, a wiring line, and the like. For example, the second interconnection structure 5650 may include a channel contact 5650A, a bit line contact 5650B, and a bit line 5650C, as configured in FIGS. 6A to 6C or FIGS. 9A to 9C. The third interconnection structure 5680 may be disposed in a third insulator 5670 and may include a via, a wiring line, and the like. The second conductive bonding pad 5660 may be disposed at a second bonding interface 5006 and may be electrically connected to the first memory cell array through the second interconnection structure 5650. The third conductive bonding pad 5690 may be disposed at the first bonding interface 5005 and may be electrically connected to the first memory cell array through the third interconnection structure 5680.

The third semiconductor structure 5600B may include a second gate stacked structure 5616, a second cell pillar 5626, a second source structure 5631, a fourth insulator 5641, a fourth interconnection structure 5651, and a fourth conductive bonding pad 5661. The second gate stacked structure 5616 may include second gate lines 5617 alternately stacked with second interlayer insulating layers 5618. The second gate lines 5817 correspond to the conductive layers described above with reference to FIGS. 6A to 6C. The second interlayer insulating layers 5818 correspond to the interlayer insulating layers described above with reference to FIGS. 6A to 6C. The second source structure 5631 may be disposed over or under the second gate stacked structure 5616. The second source structure 5631 may comprise the doped semiconductor structure described above with reference FIG. 10A. The second source structure 5631 may be electrically isolated from the first source structure 5630 and driven separately from the first source structure 5630 or may be electrically connected to the first source structure 5630 and driven in common with the first source structure 5630. The second cell pillar 5626 may be formed in a channel hole extending through the second gate stacked structure 5616. The second cell pillar 5626 may include channel structures spaced apart from each other in the same channel hole, as described above with reference to FIG. 4. The second cell pillar 5626 may include a second channel structure 5627, a second memory layer 5628, and/or a second core insulating layer 5629. The second channel structure 5627 may extend through the second gate stacked structure 5616 and may be connected to the second source structure 5631. The fourth interconnection structure 5651 may be disposed in the fourth insulator 5641. The fourth insulator 5641 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the fourth insulator 5641 may include an interposing insulating layer 5641A, a first insulating layer 5641B, an etch stop layer 5641C, and a second insulating layer 5641D corresponding to the configuration of FIGS. 6A to 6C. Furthermore, the fourth insulator 5641 may further include a third insulating layer 5641E positioned between the second insulating layer 5641D and the second semiconductor structure 5600A. The fourth interconnection structure 5651 may include a via, a wiring line, and the like. For example, the fourth interconnection structure 5651 may include a channel contact 5651A, a bit line contact 5651B, and a bit line 5651C, as configured in FIGS. 6A to 6C or FIGS. 9A to 9C. For example, the fourth interconnection structure 5651 may include a bit line 5653. The fourth conductive bonding pad 5661 may be disposed at the second bonding interface 5006 and may be electrically connected to the second memory cell array through the fourth interconnection structure 5651.

The first conductive bonding pad 5550 may be electrically connected to the third conductive bonding pad 5690 at the first bonding interface 5005, and the first memory cell array may be electrically connected to the peripheral circuit structure through the first conductive bonding pad 5550 and the third conductive bonding pad 5690. The second conductive bonding pad 5660 may be electrically connected to the fourth conductive bonding pad 5661 at the second bonding interface 5006, and the second memory cell array may be electrically connected to the first memory cell array through the second conductive bonding pad 5660 and the fourth conductive bonding pad 5661.

The semiconductor memory device may be manufactured using a method such as hybrid bonding, metal bonding, insulator bonding, or semiconductor bonding. The semiconductor memory device may be manufactured by manufacturing a first wafer including the peripheral circuit structure, a second wafer including the first memory cell array, and a third wafer including the second memory cell array, and bonding the first to third wafers together. For example, the second wafer may be flipped and bonded to the third wafer, and a substrate of the second wafer may be removed to form the first source structure 5630. The second wafer and the first wafer may be bonded, and a substrate of the third wafer may be removed to form the second source structure 5631.

FIG. 26D is a diagram illustrating the structure of a semiconductor memory device according to an embodiment.

Referring to FIG. 26D, the semiconductor memory device may include a first semiconductor structure 5700A, a second semiconductor structure 5700B, a third semiconductor structure 5800A, and a fourth semiconductor structure 5800B. Bonding interfaces 5007, 5008, and 5009 may be located in the semiconductor memory device, and the first semiconductor structure 5700A, the second semiconductor structure 5700B, the third and the fourth semiconductor structure 5800A, semiconductor structure 5800B may be distinguished by the bonding interfaces 5007, 5008, and 5009. The third semiconductor structure 5800A and the fourth semiconductor structure 5800B may be disposed between the first semiconductor structure 5700A and the second semiconductor structure 5700B. The first semiconductor structure 5700A may include a first peripheral circuit structure, the second semiconductor structure 5700B may include a second peripheral circuit structure, the third semiconductor structure 5800A may include a first memory cell array, and the fourth semiconductor structure 5800B may include a second memory cell array.

The first semiconductor structure 5700A may include a first substrate 5710, a first transistor 5720, a first insulator 5730, a first interconnection structure 5740, and a first conductive bonding pad 5750. The first transistor 5720 may be included in the first peripheral circuit structure. The first peripheral circuit structure may include a row decoder, a page buffer, an input/output circuit, a logic circuit, and the like. The first interconnection structure 5740 may be disposed in the first insulator 5730 and may include a via, a wiring line, and the like. The first conductive bonding pad 5750 may be disposed at a first bonding interface 5007 and may be electrically connected to the first peripheral circuit structure through the first interconnection structure 5740.

The second semiconductor structure 5700B may include a second substrate 5711, a second transistor 5721, a second insulator 5731, a second interconnection structure 5741, and a second conductive bonding pad 5751. The second transistor 5721 may be included in the second peripheral circuit structure. The second peripheral circuit structure may include a row decoder, a page buffer, an input/output circuit, a logic circuit, and the like. The second interconnection structure 5741 may be disposed in the second insulator 5731 and may include a via, a wiring line, and the like. The second conductive bonding pad 5751 may be disposed at a second bonding interface 5008 and may be electrically connected to the second peripheral circuit structure through the second interconnection structure 5741.

The third semiconductor structure 5800A may include a first gate stacked structure 5810, a first cell pillar 5820, a first source structure 5830, a third insulator 5840, a third interconnection structure 5850, a third conductive bonding pad 5860, and a first contact plug 5870. The first gate stacked structure 5810 may include first gate lines 5811 alternately stacked with first interlayer insulating layers 5812. The first gate lines 5811 correspond to the conductive layers described above with reference to FIGS. 6A to 6C. The first interlayer insulating layers 5812 correspond to the interlayer insulating layers described above with reference to FIGS. 6A to 6C. The first source structure 5830 may be disposed over or under the first gate stacked structure 5810. The first source structure 5830 may comprise the doped semiconductor structure described above with reference FIG. 10A. The first cell pillar 5820 may be formed in a channel hole extending through the first gate stacked structure 5810. The first cell pillar 5820 may include channel structures spaced apart from each other in the same channel hole, as described above with reference to FIG. 4. The first cell pillar 5820 may include a first channel structure 5821, a first memory layer 5822, and/or a first core insulating layer 5823. The first channel structure 5821 may extend through the first gate stacked structure 5810 and may be connected to the first source structure 5830. The third interconnection structure 5850 may be disposed in the third insulator 5840. The third insulator 5840 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the third insulator 5840 may include an interposing insulating layer 5840A, a first insulating layer 5840B, an etch stop layer 5840C, and a second insulating layer 5840D corresponding to the configuration of FIGS. 6A to 6C. Furthermore, the third insulator 5840 may further include a third insulating layer 5840E positioned between the second insulating layer 5840D and the first semiconductor structure 5700A. The third interconnection structure 5850 may include a via, a wiring line, and the like. For example, the third interconnection structure 5850 may include a channel contact 5850A, a bit line contact 5850B, and a bit line 5850C, as configured in FIGS. 6A to 6C or FIGS. 9A to 9C. The third conductive bonding pad 5860 may be disposed at the first bonding interface 5007 and may be electrically connected to the first memory cell array through the third interconnection structure 5850.

The fourth semiconductor structure 5800B may include a second gate stacked structure 5816, a second cell pillar 5826, a second source structure 5831, a fourth insulator 5841, a fourth interconnection structure 5851, a fourth conductive bonding pad 5861, and a second contact plug 5880. The second gate stacked structure 5816 may include second gate lines 5817 alternately stacked with second interlayer insulating layers 5818. The second gate lines 5817 correspond to the conductive layers described above with reference to FIGS. 6A to 6C. The second interlayer insulating layers 5818 correspond to the interlayer insulating layers described above with reference to FIGS. 6A to 6C. The second source structure 5831 may be disposed over or under the second gate stacked structure 5816. The second source structure 5831 may comprise the doped semiconductor structure described above with reference FIG. 10A. The second source structure 5831 may be electrically connected to the first source structure 5830 and driven in common with the first source structure 5830. The second cell pillar 5826 may be formed in a channel hole extending through the second gate stacked structure 5816. The second cell pillar 5826 may include channel structures spaced apart from each other in the same channel hole, as described above with reference to FIG. 4. The second cell pillar 5826 may include a second channel structure 5827, a second memory layer 5828, and/or a second core insulating layer 5829. The second channel structure 5827 may extend through the second gate stacked structure 5816 and may be connected to the second source structure 5831. The fourth interconnection structure 5851 may be disposed in the fourth insulator 5841. The fourth insulator 5841 may be configured to include an interposing insulating layer, a first insulating layer, an etch stop layer, and a second insulating layer as described in FIGS. 6A to 6C, or an interposing insulating layer, a first insulating layer, insulating lines, an etch stop layer, and a second insulating layer as described in FIGS. 9A to 9C. In an embodiment, the fourth insulator 5841 may include an interposing insulating layer 5841A, a first insulating layer 5841B, an etch stop layer 5841C, and a second insulating layer 5841D corresponding to the configuration of FIGS. 6A to 6C. Furthermore, the fourth insulator 5841 may further include a third insulating layer 5841E positioned between the second insulating layer 5841D and the second semiconductor structure 5700B. The fourth interconnection structure 5851 may include a via, a wiring line, and the like. For example, the fourth interconnection structure 5851 may include a channel contact 5851A, a bit line contact 5851B, and a bit line 5851C, as configured in FIGS. 6A to 6C or FIGS. 9A to 9C. The fourth conductive bonding pad 5861 may be disposed at the second bonding interface 5008 and may be electrically connected to the second memory cell array through the fourth interconnection structure 5851.

The first conductive bonding pad 5750 may be electrically connected to the third conductive bonding pad 5860 at the first bonding interface 5007, and the first memory cell array may be electrically connected to the first peripheral circuit structure through the first conductive bonding pad 5750 and the third conductive bonding pad 5860. The second conductive bonding pad 5751 may be electrically connected to the fourth conductive bonding pad 5861 at the second bonding interface 5008, and the second memory cell array may be electrically connected to the second peripheral circuit structure through the second conductive bonding pad 5751 and the fourth conductive bonding pad 5861. The first source structure 5830 may be bonded to the second source structure 5831 at a third bonding interface 5009. Thus, the first memory cell array may be electrically connected to the second memory cell array.

The first contact plug 5870 may extend through the third insulator 5840 or a dummy stack, and the second contact plug 5880 may extend through the fourth insulator 5841 or a dummy stack. The first contact plug 5870 may be connected to the second contact plug 5880, and the first peripheral circuit structure may be connected to the second peripheral circuit structure through the first conductive bonding pad 5750, the third conductive bonding pad 5860, the first contact plug 5870, the second contact plug 5880, the fourth conductive bonding pad 5861, and the second conductive bonding pad 5751.

The semiconductor memory device may be manufactured using a method such as hybrid bonding, metal bonding, insulator bonding, or semiconductor bonding. The semiconductor memory device may be manufactured by manufacturing a first wafer including the first peripheral circuit structure, a second wafer including the first memory cell array, a third wafer including the second peripheral circuit structure, and a fourth wafer including the second memory cell array, and bonding the first to fourth wafers together. For example, the second wafer may be flipped and bonded to the first wafer, and a substrate of the second wafer may be removed to form the first source structure 5830. The fourth wafer may be flipped and bonded to the third wafer, and a substrate of the fourth wafer may be removed to form the second source structure 5831. The second wafer may be bonded to the fourth wafer.

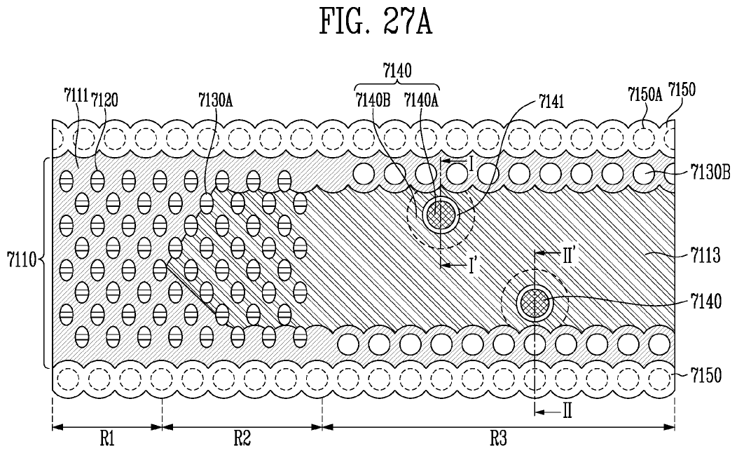

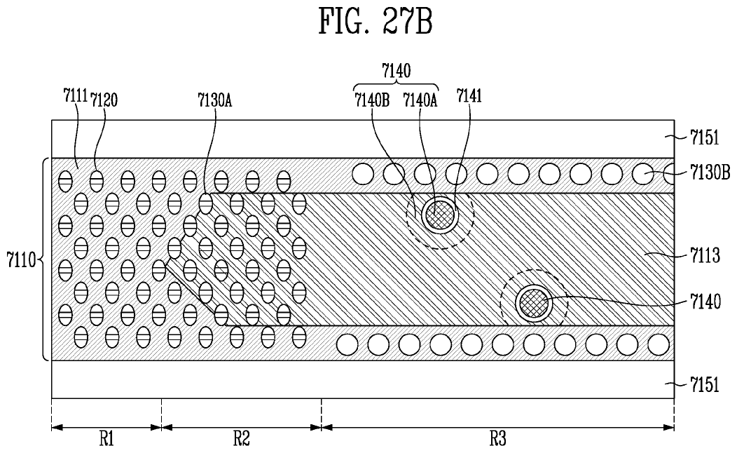

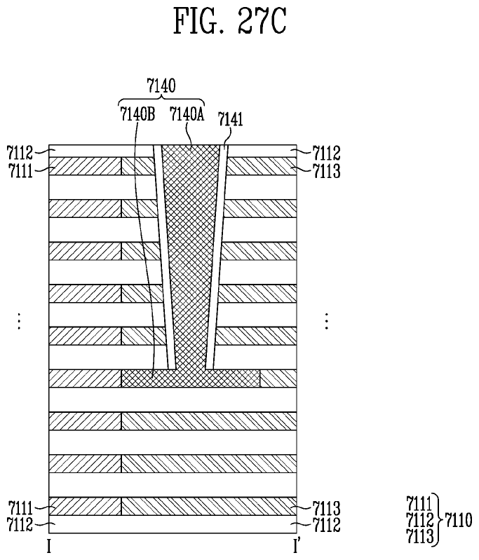

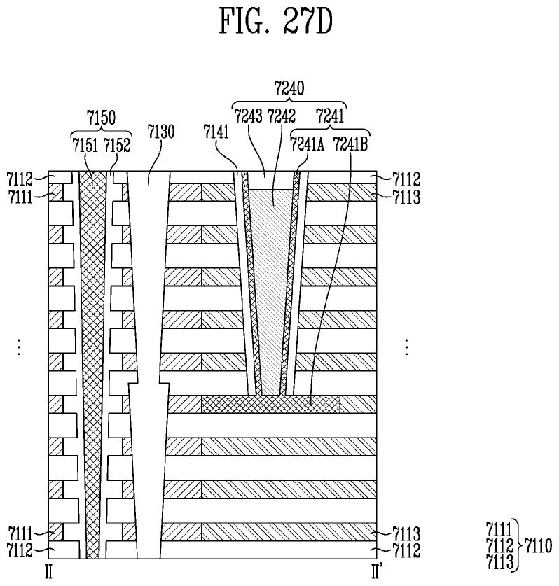

FIGS. 27A to 27D are a diagram illustrating the structure of a semiconductor memory device according to an embodiment. FIG. 27C is a cross-sectional view taken along line I-I′ of FIG. 27A. FIG. 27D is a modified example of FIG. 27C and is a cross-sectional view taken along line II-II′ of FIG. 27A.

Referring to FIGS. 27A and 27B, the semiconductor memory device may include a gate stacked structure 7110, cell pillars 7120, dummy pillars 7130A, supports 7130B, a contact plug 7140 or 7240, an insulating spacer 7141, and slit structures 7150 or 7151.

The slit structures 7150 or 7151 may extend in one direction, and the gate stacked structure 7110 may be disposed between the slit structures 7150 or 7151. Referring to FIG. 27A, slit structures 7150 may be formed within a slit defined by extending and connecting holes 7150A arranged in a row, and may have irregularities on their sidewalls. Referring to FIG. 27B, slit structure 7151 may be formed within a line-shaped slit, and the sidewalls may have a linear shape without irregularities. Each of the slit structures 7150 and 7151 may include an insulating material, a semiconductor material, and/or a conductive material.

Referring to FIGS. 27A and 27D, the gate stacked structure 7110 may include gate lines 7111 and dielectric layers 7113. The gate stacked structure 7110 may further include insulating layers (e.g., 7112 in FIGS. 27C and 27D), which correspond to the interlayer insulating layers described above with reference to FIGS. 6A to 6C. The gate stacked structure 7110 may include a cell region R1, a dummy region R2, and a contact region R3. The dummy region R2 may be located between the cell region R1 and the contact region R3. The gate lines 7111 of the gate stacked structure 7110 may comprise conductive layers stacked in a vertical direction to be spaced apart from each other. Each of the gate lines 7111 may extend through the cell region R1 and portions of the dummy and contact regions R2 and R3 of the gate stacked structure 7110. The dielectric layers 7113 may be stacked in the vertical direction to be spaced apart from each other. Each of the dielectric layers 7113 may be disposed within other portions of the dummy and contact regions R2 and R3 of the gate stacked structure 7110. Each of the insulating layers (e.g., 7112 in FIGS. 27C and 27D) may extend through the cell region R1, the dummy region R2, and contact region R3 of the gate stacked structure. The gate lines 7111 are alternately stacked with the insulating layers (e.g., 7112 in FIGS. 27C and 27D), and the insulating layers may extend between the stacked dielectric layers 7113. In other word, each of the insulating layers (e.g., 7112 in FIGS. 27C and 27D) may protrude laterally farther than the gate lines 7111. Together with the dielectric layers 7113, theses protruding portions define the other portions the dummy and contact regions R2 and R3 of the gate stacked structure. Each of the gate lines 7111 may surround a corresponding dielectric layer of the dielectric layers 7113. The interface between the gate line 7111 and the dielectric layer 7113 may be uneven or corrugated, or may have a linear shape.

The cell pillars 7120 may be disposed in the cell region R1 of the gate stacked structure 7110. The cell pillars 7120 may be formed in a channel hole extending in the vertical direction through the gate stacked structure 7110, and include channel structures spaced apart from each other in the same channel hole. Memory cells may be stacked along each of the channel structures. The dummy pillars 7130A may be extend through the dummy region R2 of the gate stacked structure 7110. The dummy pillars 7130A may be formed in a dummy hole extending in the vertical direction through the gate stacked structure 7110, and include dummy channel structures spaced apart from each other in the same dummy hole. The supports 7130B may be disposed in the contact region R3 of the gate stacked structure 7110. The supports 7130B may be disposed between the dielectric layers 7113 and the slit structures 7150 or 7151, and may extend through the gate lines 7111 and the insulating layers (e.g., 7112 in FIGS. 27C and 27D).

Referring to FIG. 27A and FIG. 27C, the contact plug 7140 may include a pillar portion 7140A and a contact portion 7140B protruding from the pillar portion 7140A. The pillar portion 7140A and the contact portion 7140B may be formed as a single layer or may be formed as separate layers. The pillar portion 7140A may extend in the vertical direction through the insulating layers 7112 and the dielectric layers 7113. The contact portion 7140B may be disposed at a level where each of a corresponding dielectric layer 7113 and a corresponding gates line 7111 is disposed. The contact portion 7140B may extend in a horizontal direction to be electrically connected to the corresponding gate line of the gate lines 7111. In other words, the contact portion 7140B may protrude laterally farther than the pillar portion 7140A to contact the corresponding gate line, and the pillar portion 7140A may extend through at least one of the insulating layers 7112 and at least one of the dielectric layers 7113. The insulating spacer 7141 may surround the pillar portion 7140A. The semiconductor memory device may include a plurality of contact plugs 7140, and each of the plurality of contact plugs 7140 may extend to a different depth and be connected to a different gate line 7111. In an embodiment, the pillar portion 7140A and the contact portion 7140B are formed as a single unified structure, for example, formed in one process using the same material. Alternatively, the pillar portion 7140A and the contact portion 7140B may be formed separately and connected together.

Referring to FIGS. 27A and 27D, the semiconductor memory device may include a gate stacked structure 7110, cell pillars 7120, a contact plug 7240, an insulating spacer 7141, dummy pillars 7130A, supports 7130B, and a slit structure 7150. The gate stacked structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113.

The supports 7130B may extend through the gate lines 7111 that are alternately stacked with the insulating layers 7112. The supports 7130B may each include an insulating material, a semiconductor material, and/or a conductive material. The slit structure 7150 may include a structure formed in a slit used as a passage for a replacement process and may extend between adjacent gate stacked structures 7110. For example, the slit structure 7150 may include a conductive layer 7151 and an insulating spacer 7152 surrounding sidewalls of the conductive layer 7151. The insulating spacer 7152 may include protrusions protruding toward the gate lines 7111.

The contact plug 7240 may include a barrier layer 7241, a gap-fill insulating layer 7242, and a contact pad 7243. The gap-fill insulating layer 7242 may extend in the vertical direction through the dielectric layers 7113 and the insulating layers 7112. The contact pad 7243 may be disposed over the gap-fill insulating layer 7242 and may include metal such as tungsten. The barrier layer 7241 may include a pillar portion 7241A and a contact portion 7241B. The pillar portion 7241A may surround sidewalls of the gap-fill insulating layer 7242 and the contact pad 7243. The contact portion 7241B may be disposed below a lower surface of the gap-fill insulating layer 7242 and may extend in the horizontal direction to electrically connect to the gate line 7111. The insulating spacer 7141 may surround the pillar portion 7241A. The semiconductor memory device may include a plurality of contact plugs 7240, and each of the plurality of contact plugs 7240 may extend to a different depth and is connected to a different gate line 7111.

The semiconductor memory device may be manufactured using a replacement process. For example, the gate stacked structure 7110 may be formed by forming a stack including sacrificial layers alternately stacked with the insulating layers 7112 and replacing the sacrificial layers with the gate lines 7111 through the slit. The stack may include a cell region, a dummy region, and a contact region, and the sacrificial layers may remain in a portions of the dummy and contact regions spaced apart from the slit. The dielectric layers 7113 of the gate stacked structure 7110 may be the remaining sacrificial layers. A contact hole extending through the insulating layers 7112 and the dielectric layers 7113 may be formed, and the insulating spacer 7141 may be formed on sidewalls of the stack exposed by the contact hole. By etching the dielectric layer 7113 exposed at a lower end of the insulating spacer 7141 and the contact hole, a lower end of the contact hole may be expanded in the horizontal direction to expose the gate line 7111. The contact plug 7140 or the contact plug 7240 may be formed within the insulating spacer 7141 formed in the contact hole.

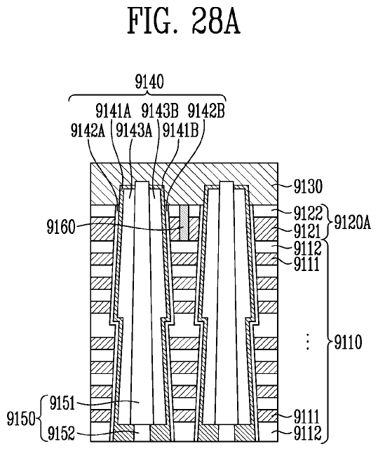

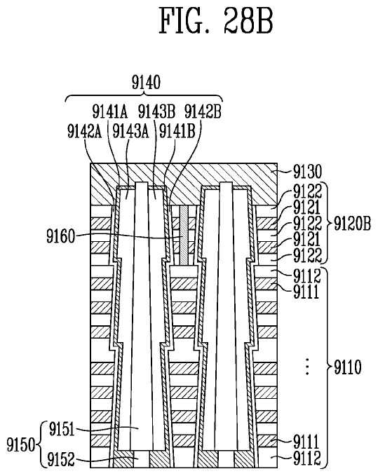

FIGS. 28A and 28B are diagrams illustrating the structure of a semiconductor memory device according to an embodiment.

Referring to FIGS. 28A and 28B, a semiconductor memory device may include a first gate stacked structure 9110, a second gate stacked structure 9120A or 9120B, a source structure 9130, a cell pillar 9140, and an isolation insulating structure 9160. The first gate stacked structure 9110 may include first gate lines 9111 alternately stacked with first interlayer insulating layers 9112. The first gate lines 9111 may be word lines or a drain select line. The source structure 9130 may be disposed over the first gate stacked structure 9110.

The second gate stacked structure 9120A or 9120B may be disposed between the first gate stacked structure 9110 and the source structure 9130. Referring to FIG. 28A, the second gate stacked structure 9120A may include a second gate line 9121 alternately stacked with second interlayer insulating layers 9122. Referring to FIG. 28B, the second gate stacked structure 9120B may include second gate lines 9121 alternately stacked with second interlayer insulating layers 9122. The second gate line 9121 may be a source select line. The second gate line 9121 may be thicker than the first gate line 9111 or have substantially the same thickness as the first gate line 9111. The second gate line 9121 may include a different material from the first gate line 9111. For example, the first gate line 9111 may include metal such as tungsten (W) or molybdenum (Mo), and the second gate line 9121 may include polysilicon. Consecutive second gate lines 9121 disposed at the same level may be insulated by an isolation insulating structure 9160. In a plan view, the isolation insulating structures 9160 may extend in a line or a wave or zigzag shape. The isolation insulating structure 9160 may overlaps the first gate line 9111 in a vertical direction.

The cell pillars 9140 may extend through the first gate stacked structure 9110 and the second gate stacked structure 9120A or 9120B. Each of the cell pillars 9140 may include channel structures spaced apart from each other in the same channel hole, as described above with reference to FIG. 4. In an embodiment, each of the cell pillars 9140 may include a first channel structure 9141A, a second channel structure 9141B, a first memory layer 9142A, a second memory layer 9142B, a first core insulating layer 9143A, a second core insulating layer 9143B, and a vertical insulating structure 9150. The vertical insulating structure 9150 may include a first vertical insulating structure 1951 and a second vertical insulating structure 9152, as described above reference to FIG. 6B.

The first gate stacked structure 9110 and the second gate stacked structure 9120A or 9120B may be formed by separate processes. For example, the second gate stacked structure 9120A or 9120B may be formed on a substrate. At least one conductive layer and the second interlayer insulating layers 9122 may be formed, and the second gate lines 9121 and trenches between the second gate lines 9121 may be formed by etching at least one conductive layer and the second interlayer insulating layers 9122. The isolation insulating structures 9160 may be formed in the trenches. The first gate stacked structure 9110 may be formed by forming a stack including sacrificial layers alternately stacked with the first interlayer insulating layers 9112 and replacing the sacrificial layers with the first gate lines 9111. A wafer bonding process may be performed, the substrate may be removed, and the source structure 9130 may be formed. In another example, the second gate stacked structure 9120A or 9120B including at least one conductive layer and the second interlayer insulating layers 9122 may be formed on a substrate. The first gate stacked structure 9110 may be formed by forming a stack including sacrificial layers alternately stacked with the first interlayer insulating layers 9112 and replacing the sacrificial layers with the first gate lines 9111. A wafer bonding process may be performed, and a rear surface of the second gate stacked structure 9120A or 9120B may be exposed by removing the substrate. The second gate lines 9121 and trenches between the second gate lines 9121 may be formed by etching at least one conductive layer and the second interlayer insulating layers 9122, and the isolation insulating structures 9160 may be formed in the trenches. The source structure 9130 may be formed.

According to embodiments of the present disclosure, a photolithography process that targets a line-type opening such as a trench instead of a hole-type opening may be performed in patterning an etch stop layer. In an embodiment, when the photolithography process is performed to target the line-type opening rather than the hole-type opening, margins of an exposure process may be increased, and therefore, process margins of a semiconductor memory device may be secured according to embodiments of the present disclosure.

According to embodiments of the present disclosure, a part of the etch stop layer that is adjacent to a bit line contact is replaced by an insulating material that is different from the etch stop layer, and therefore, parasitic capacitance occurring due to the etch stop layer may be decreased. Accordingly, in an embodiment, operational reliability of the semiconductor memory device may be improved.

What is claimed is:

1. A semiconductor memory device, comprising:
a gate stacked structure including conductive layers, each of the conductive layers extending in a first direction and a second direction, wherein the conductive layers are stacked to be spaced apart from each other in a third direction;
a first insulating layer, an intermediate insulating layer, and a second insulating layer, which are stacked in the third direction over the gate stacked structure;
a first channel structure and a second channel structure extending through the gate stacked structure and spaced apart from each other in the second direction;
a first bit line disposed in the second insulating layer and extending in the second direction; and
a first bit line contact extending through the first insulating layer to be positioned between the first bit line and the first channel structure,
wherein the intermediated insulating layer includes a trench extending in a diagonal direction between the first and second directions, and
wherein the second insulating layer includes a horizontal portion disposed over the intermediate insulating layer, and a protrusion extending from the horizontal portion to fill the trench.

2. The semiconductor memory device of claim 1, further comprising a vertical insulating structure between the first channel structure and the second channel structure,
wherein the gate stacked structure includes a channel hole extending in the third direction, and
wherein the first channel structure, the second channel structure, and at least a portion of the vertical insulating structure are disposed in the channel hole.

3. The semiconductor memory device of claim 2, wherein a width of the channel hole in the second direction is greater than a width of the channel hole in the first direction.

4. The semiconductor memory device of claim 1, wherein the first channel structure and the second channel structure have substantially semi-ellipse shapes that are substantially symmetrical to each other.

5. The semiconductor memory device of claim 1, further comprising:
a first memory layer between the gate stacked structure and the first channel structure;
a second memory layer between the gate stacked structure and the second channel structure; and
a vertical insulating structure extending from between the first channel structure and the second channel structure to between the first memory layer and the second memory layer.

6. The semiconductor memory device of claim 1, wherein the intermediate insulating layer comprising a material different from those of the first and second insulating layers.

7. The semiconductor memory device of claim 1, wherein each of the first insulating layer and the second insulating layer has a lower relative dielectric constant than the intermediate insulating layer.

8. The semiconductor memory device of claim 1, wherein an axis extending in the diagonal direction and an axis extending in the second direction cross at an angle of 10° to 45°.

9. The semiconductor memory device of claim 1, further comprising:
a second bit line disposed in the second insulating layer and extending in the second direction; and
a second bit line contact extending through the first insulating layer to be positioned between the second bit line and the second channel structure.

10. The semiconductor memory device of claim 9,
wherein the protrusion of the second insulating layer comprises:
a part interposed between the first bit line contact and the second bit line contact; and
a part interposed between the first bit line and the second bit line.

11. The semiconductor memory device of claim 1, further comprising:
a semiconductor structure disposed over a surface of the first bit line opposite to the intermediate layer;
a conductive bonding pads between the semiconductor structure and the first bit line.

12. The semiconductor memory device of claim 11, wherein the semiconductor structure includes a memory cell array or a peripheral circuit structure.

13. The semiconductor memory device of claim 1, further comprising:
a first semiconductor structure disposed over a surface of the first bit line opposite to the intermediate layer;
a second semiconductor structure disposed over a surface of the gate stacked structure opposite to the first insulating layer;
a first conductive bonding pads between the first semiconductor structure and the first bit line; and
a second conductive bonding pads between the second semiconductor structure and the gate stacked structure.

14. The semiconductor memory device of claim 13, wherein one of the first semiconductor structure and the second semiconductor structure includes a memory cell array, and the other includes a peripheral circuit structure.

15. The semiconductor memory device of claim 1, wherein the gate stacked structure further includes interlayer insulating layers alternately stacked with the conductive layers in the third direction,
wherein each of the interlayer insulating layers protrudes laterally farther than the conductive layers to define a contact region.

16. The semiconductor memory device of claim 15 further comprising:
sacrificial layers alternately stacked with the interlayer insulating layers in the contact region in the third direction;
a contact plug including a contact portion disposed at a level a corresponding conducive layer of the conductive layers, and a pillar portion extending though at least one of the interlayer insulating layers in the contact region and at least one of the sacrificial layers; and
an insulating spacer surrounding the pillar portion of the contact plug,
wherein the contact portion of the contact plug protrudes laterally farther than the pillar portion of the contact plug to contact the corresponding conductive layer.

17. The semiconductor memory device of claim 1,
wherein the gate stacked structure includes a first gate stacked structure and the second gate stacked structure stacked in the third direction,
wherein the conductive layers include first gate lines of the first gate stacked structure and second gate lines of the second gate stacked structure,
wherein the second gate lines are laterally spaced apart from each other by an isolation insulating structure which overlaps the first gate lines in the third direction.

18. A semiconductor memory device, comprising:
a gate stacked structure including conductive layers, each of the conductive layers extending in a first direction and a second direction, wherein the conductive layers are stacked to be spaced apart from each other in a third direction;
a first channel structure and a second channel structure extending through the gate stacked structure and spaced apart from each other in the second direction;
a first insulating layer, an intermediate insulating layer, and a second insulating layer, which are stacked in the third direction over the gate stacked structure;
a first insulating line and a second insulating line extending through the intermediate insulating layer and the first insulating layer, extending in the second direction, and spaced apart from each other in the first direction;
a first bit line contact extending through the first insulating line and the first insulating layer to overlap the first channel structure in the third direction; and
a second bit line contact extending through the second insulating line and the first insulating layer to overlap the second channel structure in the third direction.

19. The semiconductor memory device of claim 18, further comprising a vertical insulating structure between the first channel structure and the second channel structure,
wherein the gate stacked structure includes a channel hole that extends in the third direction, and
wherein the first channel structure, the second channel structure, and the vertical insulating structure are disposed in the channel hole.

20. The semiconductor memory device of claim 19, wherein a width of the channel hole in the second direction is greater than a width of the channel hole in the first direction.

21. The semiconductor memory device of claim 18, wherein the first channel structure and the second channel structure have substantially semi-ellipse shapes that are substantially symmetrical to each other.

22. The semiconductor memory device of claim 18, further comprising:
a first memory layer between the gate stacked structure and the first channel structure;
a second memory layer between the gate stacked structure and the second channel structure; and
a vertical insulating structure extending from between the first channel structure and the second channel structure to between the first memory layer and the second memory layer.

23. The semiconductor memory device of claim 18, wherein the intermediate insulating layer comprising a material different from those of the first and second insulating layers and the first and second insulating lines.

24. The semiconductor memory device of claim 18, wherein each of the first insulating layer, the first insulating line, the second insulating line, and the second insulating layer has a lower relative dielectric constant than the intermediated insulating layer.

25. The semiconductor memory device of claim 18, wherein the first bit line contact and the second bit line contact are aligned with each other in a diagonal direction between the first direction and the second direction.

26. The semiconductor memory device of claim 25, wherein an axis extending in the diagonal direction and an axis extending in the second direction cross at an angle of 10° to 45°.

27. The semiconductor memory device of claim 18, further comprising:
a first bit line disposed over the first insulating line and extending through the second insulating layer to be coupled to the first bit line contact and
a second bit line disposed over the second insulating line and extending through the second insulating layer to be coupled to the second bit line contact.

28. The semiconductor memory device of claim 18, further comprising:
a bit line extending through the second insulating layer;
a semiconductor structure disposed over a surface of the bit line opposite to the intermediate layer;
a conductive bonding pads between the semiconductor structure and the bit line.

29. The semiconductor memory device of claim 28, wherein the semiconductor structure includes a memory cell array or a peripheral circuit structure.

30. The semiconductor memory device of claim 18, further comprising:
a bit line extending through the second insulating layer;
a first semiconductor structure disposed over a surface of the bit line opposite to the intermediate layer;
a second semiconductor structure disposed over a surface of the gate stacked structure opposite to the first insulating layer;
a first conductive bonding pads between the first semiconductor structure and the bit line; and
a second conductive bonding pads between the second semiconductor structure and the gate stacked structure.

31. The semiconductor memory device of claim 30,
wherein one of the first semiconductor structure and the second semiconductor structure includes a memory cell array, and the other includes a peripheral circuit structure.

32. The semiconductor memory device of claim 18, wherein the gate stacked structure further includes interlayer insulating layers alternately stacked with the conductive layers in the third direction,
wherein each of the interlayer insulating layers protrudes laterally farther than the conductive layers to define a contact region.

33. The semiconductor memory device of claim 32 further comprising:
sacrificial layers alternately stacked with the interlayer insulating layers in the contact region in the third direction;
a contact plug including a contact portion disposed at a level a corresponding conducive layer of the conductive layers, and a pillar portion extending though at least one of the interlayer insulating layers in the contact region and at least one of the sacrificial layers; and
an insulating spacer surrounding the pillar portion of the contact plug,
wherein the contact portion of the contact plug protrudes laterally farther than the pillar portion of the contact plug to contact the corresponding conductive layer.

34. The semiconductor memory device of claim 18,
wherein the gate stacked structure includes a first gate stacked structure and the second gate stacked structure stacked in the third direction,
wherein the conductive layers include first gate lines of the first gate stacked structure and second gate lines of the second gate stacked structure,
wherein the second gate lines are laterally spaced apart from each other by an isolation insulating structure which overlaps the first gate lines in the third direction.
